(19) United States
(12) Patent Application Publication
(10) Pub. No.: US 2021/0325861 A1
(43) Pub. Date: Oct. 21, 2021

(54) METHODS AND APPARATUS TO AUTOMATICALLY UPDATE ARTIFICIAL INTELLIGENCE MODELS FOR AUTONOMOUS FACTORIES

(71) Applicant: Intel Corporation, Santa Clara, CA (US)

(72) Inventors: Minmin Hou, Santa Clara, CA (US); Rita Wouhaybi, Portland, OR (US); Samudyatha C. Kaira, Portland, OR (US)

(21) Appl. No.: 17/359,206

(22) Filed: Jun. 25, 2021

Related U.S. Application Data
(60) Provisional application No. 63/182,585, filed on Apr. 30, 2021.

(51) Int. Cl. G05B 19/418; G06N 20/00

(52) U.S. Cl. CPC G05B 19/41885; G05B 19/41835; G05B 2219/23005; G06N 20/00; G05B 2219/23288; G05B 19/41875

(57) ABSTRACT

Methods, apparatus, systems, and articles of manufacture are disclosed for automatically updating artificial intelligence models operating on data of a first factory production line, the apparatus comprising, an intelligent trigger circuitry to trigger an automated model update process, an automated model search circuitry to, in response to a model update, generate a plurality of candidate artificial intelligence models, and an intelligent model deployment circuitry to output a prediction of an artificial intelligence model combination to improve prediction performance over time.

### RELATED APPLICATION

This patent claims the benefit of U.S. Provisional Patent Application No. 63/182,585, filed Apr. 30, 2021, which is hereby incorporated herein by reference in its entirety. Priority to U.S. Patent Application No. 63/182,585 is hereby claimed.

### FIELD OF THE DISCLOSURE

This disclosure relates generally to machine learning, and, more particularly, to methods and apparatus to automatically update artificial intelligence models for autonomous factories.

### BACKGROUND

Data collection and technology for data analysis continues to advance at a rapid pace. For example, factories that manufacture products through the use of assembly lines may gather data throughout the manufacturing process. In some examples, a first part is produced on a first assembly (e.g., production) line, and a second part that is identical to the first part may be produced on a second assembly line that is identical to the first assembly line. In recent years, machine learning algorithms have been used to model such data.

### BRIEF DESCRIPTION OF THE DRAWINGS

FIG. 1 illustrates an overview of an edge cloud configuration for edge computing.

FIG. 2 illustrates operational layers among endpoints, an edge cloud, and cloud computing environments.

FIG. 3 illustrates an example approach for networking and services in an edge computing system.

FIG. 4 is a block diagram of an example environment in which a model update controller circuitry operates to automatically update artificial intelligence models for autonomous factories.

FIG. 5 is a block diagram of an example implementation of the model update controller circuitry of FIG. 4.

FIG. 6 is a flowchart representative of example machine readable instructions that may be executed by example processor circuitry to implement the model update controller circuitry of FIG. 5.

FIG. 7 is a flowchart representative of example machine readable instructions that may be executed by example processor circuitry to implement the model update controller circuitry of FIG. 5.

FIG. 8 is a flowchart of the process executed by the environment of where the model update controller circuitry of FIG. 4 operates.

FIG. 9 is an illustration of a data table generated by the deployment circuitry of the model update controller circuitry of FIG. 5.

FIG. 10A provides an overview of example components for compute deployed at a compute node in an edge computing system.

FIG. 10B provides a further overview of example components within a computing device in an edge computing system.

FIG. 11 is a block diagram of an example processing platform including processor circuitry structured to execute the example machine readable instructions of FIG. 6 and FIG. 7 to implement the model update controller circuitry of FIG. 5.

FIG. 12 is a block diagram of an example implementation of the processor circuitry of FIG. 11.

FIG. 13 is a block diagram of another example implementation of the processor circuitry of FIG. 11.

FIG. 14 is a block diagram of an example software distribution platform (e.g., one or more servers) to distribute software (e.g., software corresponding to the example machine readable instructions of FIGS. 6-7) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

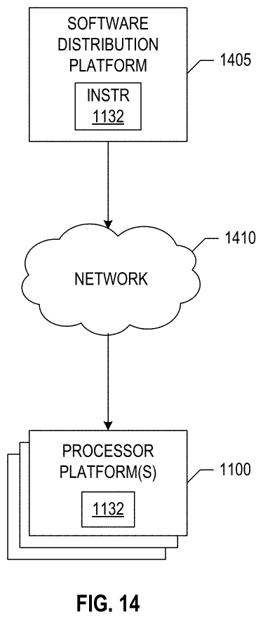

The figures are not to scale. Instead, the thickness of the layers or regions may be enlarged in the drawings. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name. As used herein, “approximately” and “about” refer to dimensions that may not be exact due to manufacturing tolerances and/or other real world imperfections. As used herein “substantially real time” refers to occurrence in a near instantaneous manner recognizing there may be real world delays for computing time, transmission, etc. Thus, unless otherwise specified, “substantially real time” refers to real time+/−1 second. As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events. As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmed with instructions to perform specific operations and including one or more semiconductor-based logic devices (e.g., electrical hardware implemented by one or more transistors). Examples of processor circuitry include programmed microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of the processing circuitry is/are best suited to execute the computing task(s).

As used herein, data is information in any form that may be ingested, processed, interpreted and/or otherwise manipulated by processor circuitry to produce a result. The produced result may itself be data.

As used herein “threshold” is expressed as data such as a numerical value represented in any form, that may be used by processor circuitry as a reference for a comparison operation.

As used herein, a model is a set of instructions and/or data that may be ingested, processed, interpreted and/or otherwise manipulated by processor circuitry to produce a result. Often, a model is operated using input data to produce output data in accordance with one or more relationships reflected in the model. The model may be based on training data. In some examples, a model is a structure of numbers and relationships to be used in artificial intelligence and/or decision-making logic.

As used herein, a configuration is an arrangement of data to identify and define how a machine is set up.

As used herein, a score may be a numerical value or dimensionless number such as a percentage.

### DETAILED DESCRIPTION

Artificial intelligence (AI), including machine learning (ML), deep learning (DL), and/or other artificial machine-driven logic, enables machines (e.g., computers, logic circuits, etc.) to use a model to process input data to generate an output based on patterns and/or associations previously learned by the model via a training process. For instance, the model may be trained with data to recognize patterns and/or associations and follow such patterns and/or associations when processing input data such that other input(s) result in output(s) consistent with the recognized patterns and/or associations.

Many different types of AI models and/or AI architectures exist. In general, AI models/architectures that are suitable to use in the example approaches disclosed herein will be artificial neural network models (e.g., convolutional neural networks, recurrent neural networks, etc.) and machine learning models (e.g., random forest classifiers, support vector machines, etc.). However, other types of machine learning models could additionally or alternatively be used such as reinforcement learning models etc.

In general, implementing a ML/AI system involves two phases, a learning/training phase and an inference phase. In the learning/training phase, a training algorithm is used to train a model to operate in accordance with patterns and/or associations based on, for example, training data. In general, the model includes internal parameters that guide how input data is transformed into output data, such as through a series of nodes and connections within the model to transform input data into output data. Additionally, hyperparameters are used as part of the training process to control how the learning is performed (e.g., a learning rate, a number of layers to be used in the machine learning model, etc.). Hyperparameters are defined to be training parameters that are determined prior to initiating the training process.

Different types of training may be performed based on the type of ML/AI model and/or the expected output. For example, supervised training uses inputs and corresponding expected (e.g., labeled) outputs to select parameters (e.g., by iterating over combinations of select parameters) for the ML/AI model that reduce model error. As used herein, labelling refers to an expected output of the machine learning model (e.g., a classification, an expected output value, etc.) Alternatively, unsupervised training (e.g., used in deep learning, a subset of machine learning, etc.) involves inferring patterns from inputs to select parameters for the ML/AI model (e.g., without the benefit of expected (e.g., labeled) outputs).

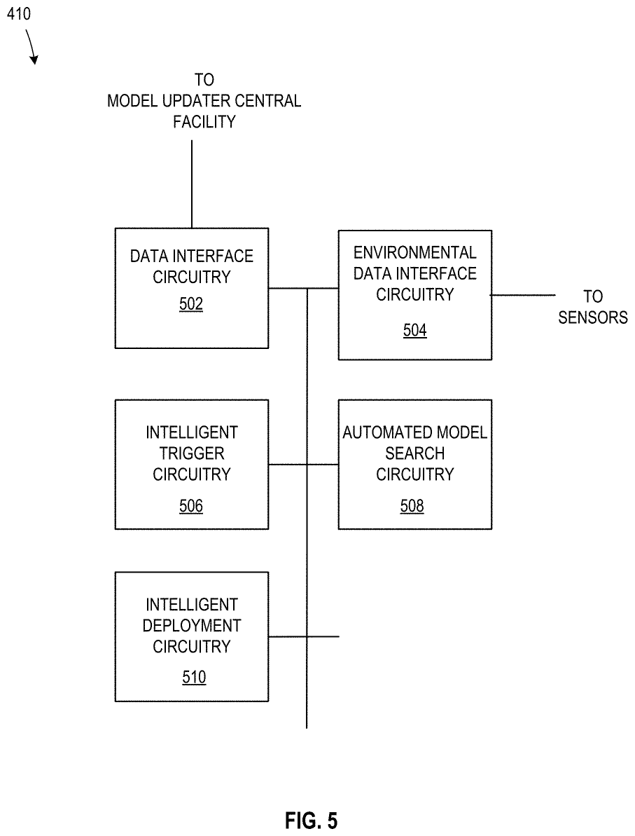

In examples disclosed herein, ML/AI models are trained based on the model type and architecture, for example, neural networks can be trained with stochastic gradient descent. However, any other training algorithm may additionally or alternatively be used. In examples disclosed herein, training is performed until the model output is converged. In examples disclosed herein, training is performed at remotely (e.g., at a central facility). In other examples, training is performed locally (e.g., at an edge device at the factory). Training is performed using hyperparameters that control how the learning is performed (e.g., a learning rate, a number of layers to be used in the machine learning model, etc.). In examples disclosed herein, hyperparameters that control the output of the model include the number of nodes, the number of layers etc. Such hyperparameters are selected by, for example, by an update of the previous model, randomly generated, or searched by an optimization algorithm. In some examples re-training may be performed. Such re-training may be performed in response to intelligent trigger circuitry as described in FIG. 5.

Training is performed using training data. In some examples supervised training is used, and the training data is labeled.

Once training is complete, the model is deployed for use as an executable construct that processes an input and provides an output based on the network of nodes and connections defined in the model. In some examples, the model is a logistic regression model, a random forest model, or a gradient boosted tree model, etc. The model is stored at the model repository as described in FIG. 5. The model may then be executed by the intelligent deployment circuitry as described in FIG. 5. In some examples, multiple models are deployed and evaluated by the intelligent deployment circuitry as described in FIG. 5.

Once trained, the deployed model may be operated in an inference phase to process data. In the inference phase, data to be analyzed (e.g., live data) is input to the model, and the model executes to create an output. This inference phase can be thought of as the AI “thinking” to generate the output based on what it learned from the training (e.g., by executing the model to apply the learned patterns and/or associations to the live data). In some examples, input data undergoes pre-processing before being used as an input to the machine learning model. Moreover, in some examples, the output data may undergo post-processing after it is generated by the AI model to transform the output into a useful result (e.g., a display of data, an instruction to be executed by a machine, etc.).

In some examples, output of the deployed model may be captured and provided as feedback. By analyzing the feedback, an accuracy of the deployed model can be determined. If the feedback indicates that the accuracy of the deployed model is less than a threshold or other criterion, training of an updated model can be triggered using the feedback and an updated training data set, hyperparameters, etc., to generate an updated, deployed model.

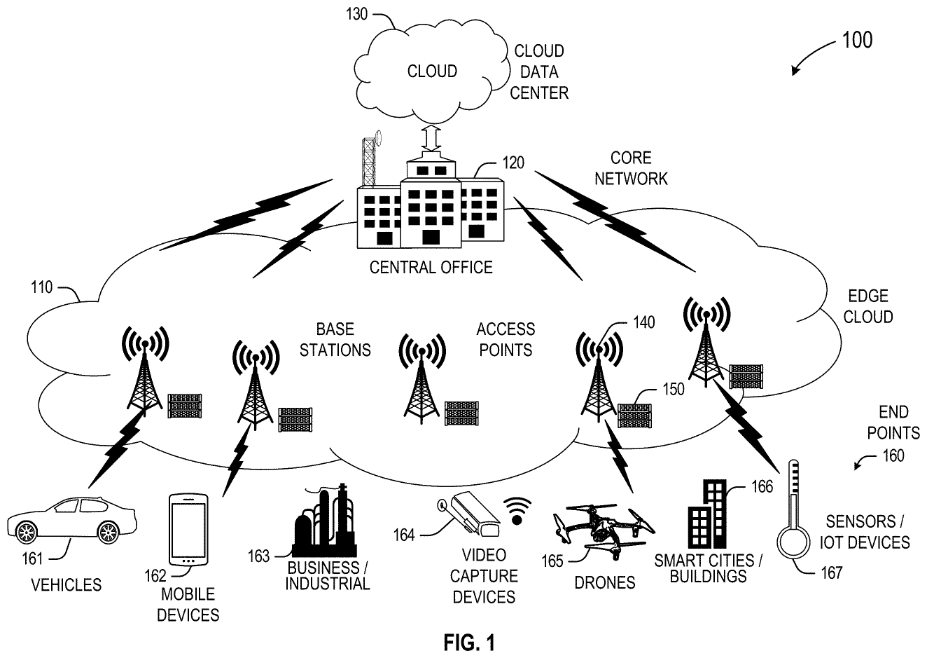

FIG. 1 is a block diagram 100 showing an overview of a configuration for edge computing, which includes a layer of processing referred to in many of the following examples as an “edge cloud”. As shown, the edge cloud 110 is co-located at an edge location, such as an access point or base station 140, a local processing hub 150, or a central office 120, and thus may include multiple entities, devices, and equipment instances. The edge cloud 110 is located much closer to the endpoint (consumer and producer) data sources 160 (e.g., autonomous vehicles 161, user equipment 162, business and industrial equipment 163, video capture devices 164, drones 165, smart cities and building devices 166, sensors and IoT devices 167, etc.) than the cloud data center 130. Compute, memory, and storage resources which are offered at the edges in the edge cloud 110 are critical to providing ultra-low latency response times for services and functions used by the endpoint data sources 160 as well as reduce network backhaul traffic from the edge cloud 110 toward cloud data center 130 thus improving energy consumption and overall network usages among other benefits.

Compute, memory, and storage are scarce resources, and generally decrease depending on the edge location (e.g., fewer processing resources being available at consumer endpoint devices, than at a base station, than at a central office). However, the closer that the edge location is to the endpoint (e.g., user equipment (UE)), the more that space and power is often constrained. Thus, edge computing attempts to reduce the amount of resources needed for network services, through the distribution of more resources which are located closer both geographically and in network access time. In this manner, edge computing attempts to bring the compute resources to the workload data where appropriate, or, bring the workload data to the compute resources.

The following describes aspects of an edge cloud architecture that covers multiple potential deployments and addresses restrictions that some network operators or service providers may have in their own infrastructures. These include, variation of configurations based on the edge location (because edges at a base station level, for instance, may have more constrained performance and capabilities in a multi-tenant scenario); configurations based on the type of compute, memory, storage, fabric, acceleration, or like resources available to edge locations, tiers of locations, or groups of locations; the service, security, and management and orchestration capabilities; and related objectives to achieve usability and performance of end services. These deployments may accomplish processing in network layers that may be considered as “near edge”, “close edge”, “local edge”, “middle edge”, or “far edge” layers, depending on latency, distance, and timing characteristics.

Edge computing is a developing paradigm where computing is performed at or closer to the “edge” of a network, typically through the use of a compute platform (e.g., x86 or ARM compute hardware architecture) implemented at base stations, gateways, network routers, or other devices which are much closer to endpoint devices producing and consuming the data. For example, edge gateway servers may be equipped with pools of memory and storage resources to perform computation in real-time for low latency use-cases (e.g., autonomous driving or video surveillance) for connected client devices. Or as an example, base stations may be augmented with compute and acceleration resources to directly process service workloads for connected user equipment, without further communicating data via backhaul networks. Or as another example, central office network management hardware may be replaced with standardized compute hardware that performs virtualized network functions and offers compute resources for the execution of services and consumer functions for connected devices. Within edge computing networks, there may be scenarios in services which the compute resource will be “moved” to the data, as well as scenarios in which the data will be “moved” to the compute resource. Or as an example, base station compute, acceleration and network resources can provide services in order to scale to workload demands on an as needed basis by activating dormant capacity (subscription, capacity on demand) in order to manage corner cases, emergencies or to provide longevity for deployed resources over a significantly longer implemented lifecycle.

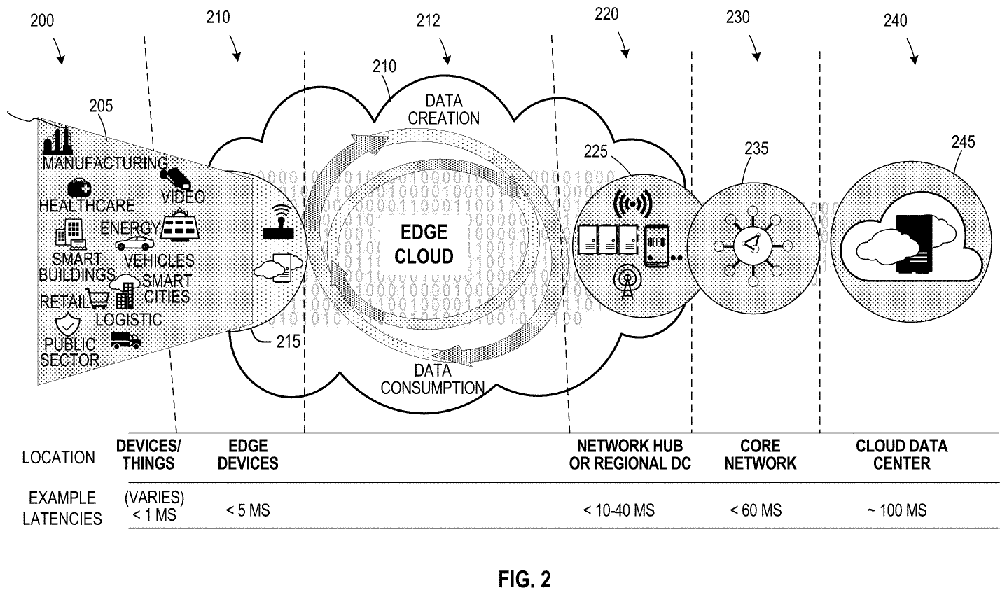

FIG. 2 illustrates operational layers among endpoints, an edge cloud, and cloud computing environments. Specifically, FIG. 2 depicts examples of computational use cases 205, utilizing the edge cloud 110 among multiple illustrative layers of network computing. The layers begin at an endpoint (devices and things) layer 200, which accesses the edge cloud 110 to conduct data creation, analysis, and data consumption activities. The edge cloud 110 may span multiple network layers, such as an edge devices layer 210 having gateways, on-premise servers, or network equipment (nodes 215) located in physically proximate edge systems; a network access layer 220, encompassing base stations, radio processing units, network hubs, regional data centers (DC), or local network equipment (equipment 225); and any equipment, devices, or nodes located therebetween (in layer 212, not illustrated in detail). The network communications within the edge cloud 110 and among the various layers may occur via any number of wired or wireless mediums, including via connectivity architectures and technologies not depicted.

Examples of latency, resulting from network communication distance and processing time constraints, may range from less than a millisecond (ms) when among the endpoint layer 200, under 5 ms at the edge devices layer 210, to even between 10 to 40 ms when communicating with nodes at the network access layer 220. Beyond the edge cloud 110 are core network 230 and cloud data center 240 layers, each with increasing latency (e.g., between 50-60 ms at the core network layer 230, to 100 or more ms at the cloud data center layer). As a result, operations at a core network data center 235 or a cloud data center 245, with latencies of at least 50 to 100 ms or more, will not be able to accomplish many time-critical functions of the use cases 205. Each of these latency values are provided for purposes of illustration and contrast; it will be understood that the use of other access network mediums and technologies may further reduce the latencies. In some examples, respective portions of the network may be categorized as “close edge”, “local edge”, “near edge”, “middle edge”, or “far edge” layers, relative to a network source and destination. For instance, from the perspective of the core network data center 235 or a cloud data center 245, a central office or content data network may be considered as being located within a “near edge” layer (“near” to the cloud, having high latency values when communicating with the devices and endpoints of the use cases 205), whereas an access point, base station, on-premise server, or network gateway may be considered as located within a “far edge” layer (“far” from the cloud, having low latency values when communicating with the devices and endpoints of the use cases 205). It will be understood that other categorizations of a particular network layer as constituting a “close”, “local”, “near”, “middle”, or “far” edge may be based on latency, distance, number of network hops, or other measurable characteristics, as measured from a source in any of the network layers 200-240.

The various use cases 205 may access resources under usage pressure from incoming streams, due to multiple services utilizing the edge cloud. To achieve results with low latency, the services executed within the edge cloud 110 balance varying requirements in terms of: (a) Priority (throughput or latency) and Quality of Service (QoS) (e.g., traffic for an autonomous car may have higher priority than a temperature sensor in terms of response time requirement; or, a performance sensitivity/bottleneck may exist at a compute/accelerator, memory, storage, or network resource, depending on the application); (b) Reliability and Resiliency (e.g., some input streams need to be acted upon and the traffic routed with mission-critical reliability, where as some other input streams may be tolerate an occasional failure, depending on the application); and (c) Physical constraints (e.g., power, cooling and form-factor).

The end-to-end service view for these use cases involves the concept of a service-flow and is associated with a transaction. The transaction details the overall service requirement for the entity consuming the service, as well as the associated services for the resources, workloads, workflows, and business functional and business level requirements. The services executed with the “terms” described may be managed at each layer in a way to assure real time, and runtime contractual compliance for the transaction during the lifecycle of the service. When a component in the transaction is missing its agreed to SLA, the system as a whole (components in the transaction) may provide the ability to (1) understand the impact of the SLA violation, and (2) augment other components in the system to resume overall transaction SLA, and (3) implement steps to remediate.

Thus, with these variations and service features in mind, edge computing within the edge cloud 110 may provide the ability to serve and respond to multiple applications of the use cases 205 (e.g., object tracking, video surveillance, connected cars, etc.) in real-time or near real-time, and meet ultra-low latency requirements for these multiple applications. These advantages enable a whole new class of applications (Virtual Network Functions (VNFs), Function as a Service (FaaS), Edge as a Service (EaaS), standard processes, etc.), which cannot leverage conventional cloud computing due to latency or other limitations.

However, with the advantages of edge computing comes the following caveats. The devices located at the edge are often resource constrained and therefore there is pressure on usage of edge resources. Typically, this is addressed through the pooling of memory and storage resources for use by multiple users (tenants) and devices. The edge may be power and cooling constrained and therefore the power usage needs to be accounted for by the applications that are consuming the most power. There may be inherent power-performance tradeoffs in these pooled memory resources, as many of them are likely to use emerging memory technologies, where more power requires greater memory bandwidth. Likewise, improved security of hardware and root of trust trusted functions are also required, because edge locations may be unmanned and may even need permissioned access (e.g., when housed in a third-party location). Such issues are magnified in the edge cloud 110 in a multi-tenant, multi-owner, or multi-access setting, where services and applications are requested by many users, especially as network usage dynamically fluctuates and the composition of the multiple stakeholders, use cases, and services changes.

At a more generic level, an edge computing system may be described to encompass any number of deployments at the previously discussed layers operating in the edge cloud 110 (network layers 200-240), which provide coordination from client and distributed computing devices. One or more edge gateway nodes, one or more edge aggregation nodes, and one or more core data centers may be distributed across layers of the network to provide an implementation of the edge computing system by or on behalf of a telecommunication service provider (“telco”, or “TSP”), internet-of-things service provider, cloud service provider (CSP), enterprise entity, or any other number of entities. Various implementations and configurations of the edge computing system may be provided dynamically, such as when orchestrated to meet service objectives.

Consistent with the examples provided herein, a client compute node may be embodied as any type of endpoint component, device, appliance, or other thing capable of communicating as a producer or consumer of data. Further, the label “node” or “device” as used in the edge computing system does not necessarily mean that such node or device operates in a client or agent/minion/follower role; rather, any of the nodes or devices in the edge computing system refer to individual entities, nodes, or subsystems which include discrete or connected hardware or software configurations to facilitate or use the edge cloud 110.

As such, the edge cloud 110 is formed from network components and functional features operated by and within edge gateway nodes, edge aggregation nodes, or other edge compute nodes among network layers 210-230. The edge cloud 110 thus may be embodied as any type of network that provides edge computing and/or storage resources which are proximately located to radio access network (RAN) capable endpoint devices (e.g., mobile computing devices, IoT devices, smart devices, etc.), which are discussed herein. In other words, the edge cloud 110 may be envisioned as an “edge” which connects the endpoint devices and traditional network access points that serve as an ingress point into service provider core networks, including mobile carrier networks (e.g., Global System for Mobile Communications (GSM) networks, Long-Term Evolution (LTE) networks, 5G/6G networks, etc.), while also providing storage and/or compute capabilities. Other types and forms of network access (e.g., Wi-Fi, long-range wireless, wired networks including optical networks) may also be utilized in place of or in combination with such 3GPP carrier networks.

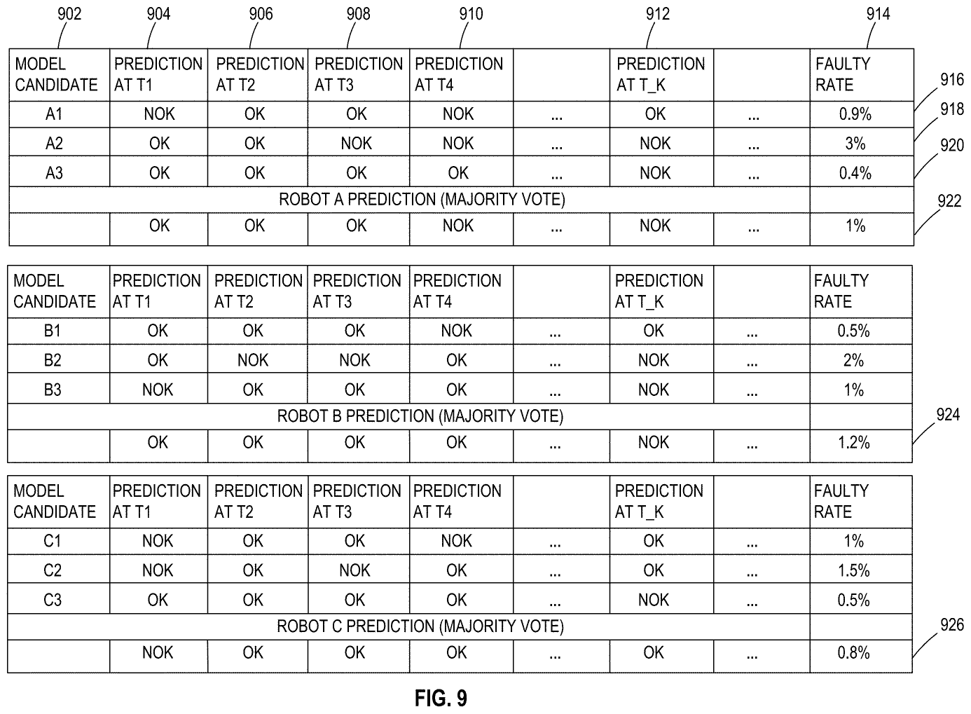

The network components of the edge cloud 110 may be servers, multi-tenant servers, appliance computing devices, and/or any other type of computing devices. For example, the edge cloud 110 may include an appliance computing device that is a self-contained electronic device including a housing, a chassis, a case or a shell. In some circumstances, the housing may be dimensioned for portability such that it can be carried by a human and/or shipped. Example housings may include materials that form one or more exterior surfaces that partially or fully protect contents of the appliance, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. Example housings and/or surfaces thereof may include or connect to mounting hardware to enable attachment to structures such as buildings, telecommunication structures (e.g., poles, antenna structures, etc.) and/or racks (e.g., server racks, blade mounts, etc.). Example housings and/or surfaces thereof may support one or more sensors (e.g., temperature sensors, vibration sensors, light sensors, acoustic sensors, capacitive sensors, proximity sensors, etc.). One or more such sensors may be contained in, carried by, or otherwise embedded in the surface and/or mounted to the surface of the appliance. Example housings and/or surfaces thereof may support mechanical connectivity, such as propulsion hardware (e.g., wheels, propellers, etc.) and/or articulating hardware (e.g., robot arms, pivotable appendages, etc.). In some circumstances, the sensors may include any type of input devices such as user interface hardware (e.g., buttons, switches, dials, sliders, etc.). In some circumstances, example housings include output devices contained in, carried by, embedded therein and/or attached thereto. Output devices may include displays, touchscreens, lights, LEDs, speakers, I/O ports (e.g., USB), etc. In some circumstances, edge devices are devices presented in the network for a specific purpose (e.g., a traffic light), but may have processing and/or other capacities that may be utilized for other purposes. Such edge devices may be independent from other networked devices and may be provided with a housing having a form factor suitable for its primary purpose; yet be available for other compute tasks that do not interfere with its primary task. Edge devices include Internet of Things devices. The appliance computing device may include hardware and software components to manage local issues such as device temperature, vibration, resource utilization, updates, power issues, physical and network security, etc. Example hardware for implementing an appliance computing device is described in conjunction with FIG. 9B. The edge cloud 110 may also include one or more servers and/or one or more multi-tenant servers. Such a server may include an operating system and implement a virtual computing environment. A virtual computing environment may include a hypervisor managing (e.g., spawning, deploying, destroying, etc.) one or more virtual machines, one or more containers, etc. Such virtual computing environments provide an execution environment in which one or more applications and/or other software, code or scripts may execute while being isolated from one or more other applications, software, code or scripts.

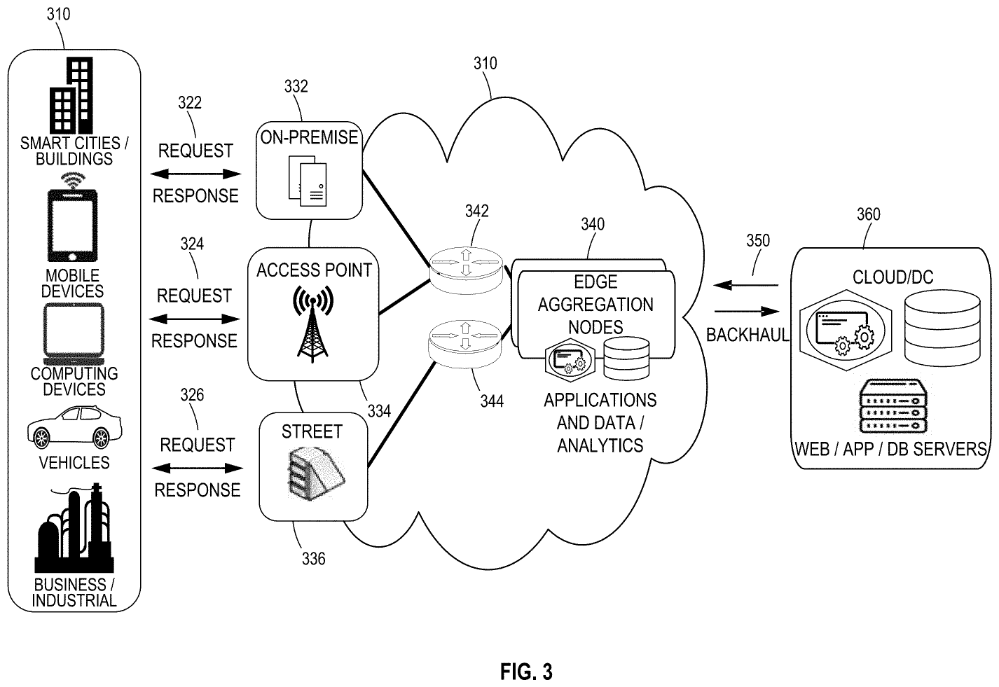

In FIG. 3, various client endpoints 310 (in the form of mobile devices, computers, autonomous vehicles, business computing equipment, industrial processing equipment) exchange requests and responses that are specific to the type of endpoint network aggregation. For instance, client endpoints 310 may obtain network access via a wired broadband network, by exchanging requests and responses 322 through an on-premise network system 332. Some client endpoints 310, such as mobile computing devices, may obtain network access via a wireless broadband network, by exchanging requests and responses 324 through an access point (e.g., cellular network tower) 334. Some client endpoints 310, such as autonomous vehicles may obtain network access for requests and responses 326 via a wireless vehicular network through a street-located network system 336. However, regardless of the type of network access, the TSP may deploy aggregation points 342, 344 within the edge cloud 110 to aggregate traffic and requests. Thus, within the edge cloud 110, the TSP may deploy various compute and storage resources, such as at edge aggregation nodes 340, to provide requested content. The edge aggregation nodes 340 and other systems of the edge cloud 110 are connected to a cloud or data center 360, which uses a backhaul network 350 to fulfill higher-latency requests from a cloud/data center for websites, applications, database servers, etc. Additional or consolidated instances of the edge aggregation nodes 340 and the aggregation points 342, 344, including those deployed on a single server framework, may also be present within the edge cloud 110 or other areas of the TSP infrastructure.

Examples disclosed herein relate to automating the development and/or the deployment of machine learning models in, for example, a factory environment. For example, machine learning models that may be deployed in edge infrastructure such as the edge infrastructure described in conjunction with FIGS. 1-3. The artificial intelligence models (e.g., machine learning models) use data generated by factories or other data sources (e.g., industrial data sources, commercial data sources, etc.). For example, manufacturing processes in factories are subject to environmental variations. For example, a temperature fluctuation in the morning using a first set of settings for manufacturing a gear, may produce unacceptable results in the afternoon, if the first set of settings are still applied. Unacceptable results may be determined as deviation from a standard or threshold as applied by the factory or the supervisor. The artificial intelligence models (e.g., machine learning models) are updated, but if a human is to update the models, there is a period of time when a model that is not as efficient as the updated model is running. This period of time wastes factory resources.

Prior techniques to automate the development and/or deployment of machine learning models include AutoML techniques as implemented by Google's Cloud AutoML, Microsoft's Azure AutoML, or DataRobot. However, these three prior techniques require humans to monitor the model performance and trigger the process to retrain the model. The model update process is more subjective as the update process is dependent on the human supervisor. Humans use time to react (e.g., substantially more time than a machine), so the model update process is discontinuous and sub-optimal models would run for longer if humans controlled the update process.

Additionally, AutoML has a limited scope and may not be applicable to industrial use cases (e.g., such as a factory production line). The prior AutoML techniques include neural network architecture search and transfer learning, and to perform such neural network architecture search a large amount of labeled training data is required, which is typically not generated by factories. Transfer learning is primarily limited to computer vision applications and natural language processing applications where mature neural network models have been trained with large datasets from sources other than the industrial use cases. In some examples, transfer learning is applicable to non-computer vision applications, but the application is limited by the need for a large dataset.

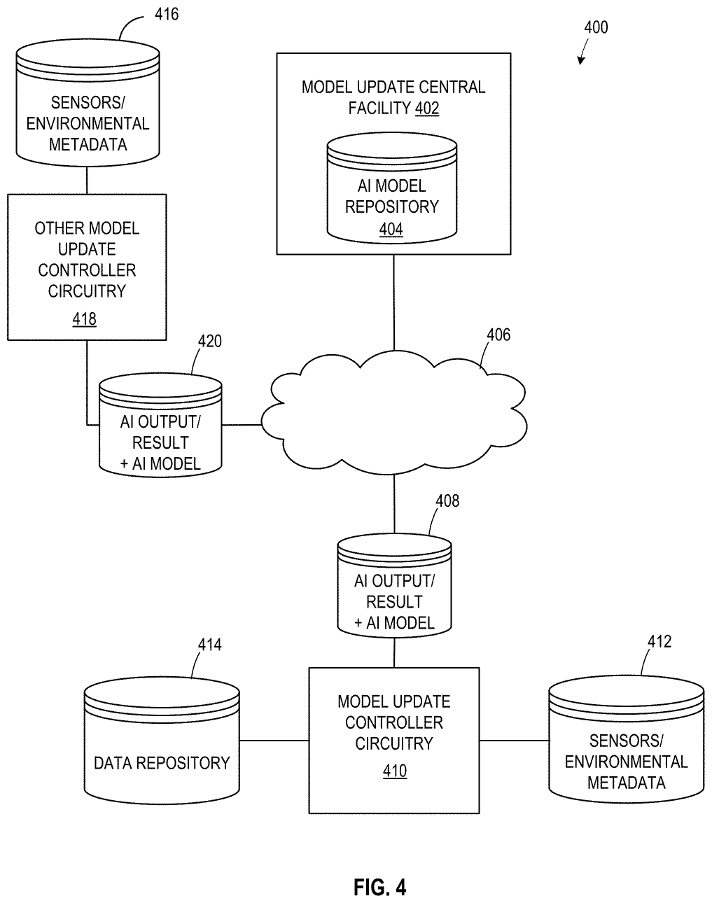

FIG. 4 is a block diagram of an example environment 400 in which model update controller circuitry operates to automatically update artificial intelligence models for autonomous factories. The example environment 400 includes an example model update central facility 402, an example network 406, an example model update controller circuitry 410, and other example model update controller circuitry 418.

The example model update central facility 402 includes an example artificial intelligence model repository 404 and is configured to receive deployed artificial intelligence models from the example model update controller circuitry 410 and the other example model update controller circuitry 418. The example model update central facility 402 is connected through a network 406 to the example model update controller circuitry 410 and the other example model update controller circuitry 418.

The example network 406 shown is the internet. The example model update controller circuitry 410 accesses the internet. Alternatively, the network 406 may be any other type of devices. In some examples, the example artificial intelligence model repository 404 and/or the example model update central facility 402 exist in the example network 406.

The example model update controller circuitry 410 is similar to the other example model update controller circuitry 418. In some examples the example model update controller circuitry 410 is identical to the other example model update controller circuitry 418. The example model update controller circuitry 410 includes access to a database 412 of sensor data or environmental metadata. The other example model update controller circuitry 418 includes access to a database 416 of sensor data or environmental metadata. The other example model update controller circuitry 418 produces an ensemble (e.g., at least one) of artificial intelligence models in the database 420 which is communicated to the example network 406 and distributed to the example model update controller circuitry 410. The example model update controller circuitry 410 produces an ensemble (e.g., at least one) of artificial intelligence models in the database 408 which is communicated to the example network 406 and distributed to the other example model update controller circuitry 418. In some examples, the models in the database 408 are directly communicated to the other example model update controller circuitry 418. The example model update controller circuitry 410 is able to use the example data repository 414 to store data regarding the artificial intelligence models produced by the example model update controller circuitry 410 or to store data regarding the artificial intelligence models produced by the other example model update controller circuitry 418, or to store hyperparameters or input data.

FIG. 5 is a block diagram of an example implementation of the model update controller circuitry 410 of FIG. 4. The example model update controller circuitry 410 includes example data interface circuitry 502, example environmental data interface circuitry 504, example intelligent trigger circuitry 506, example automated model search circuitry 508, and example intelligent deployment circuitry 510.

The example data interface circuitry 502 is implemented by a logic circuit such as, for example, a hardware (e.g., semi-conductor based) processor. However, any other type of circuitry may additionally or alternatively be used such as, for example, one or more analog or digital circuit(s), logic circuits, programmable processor(s), application specific integrated circuit(s) (ASIC(s)), programmable logic device(s) (PLD(s)), field programmable logic device(s) (FPLD(s)), digital signal processor(s) (DSP(s)), etc. The example data interface circuitry 502 is configured to communicate to the model update central facility 402 through the use of the example network 406. In some examples, the data interface circuitry 502 communicates with a corresponding data interface circuitry of the other example model update controller circuitry 418. The example data interface circuitry 502 is to communicate with the example data repository for accessing (e.g., retrieving) data regarding the artificial intelligence models produced by the example model update controller circuitry 410 or to store data regarding the artificial intelligence models produced by the other example model update controller circuitry 418, or to store hyperparameters or input data.

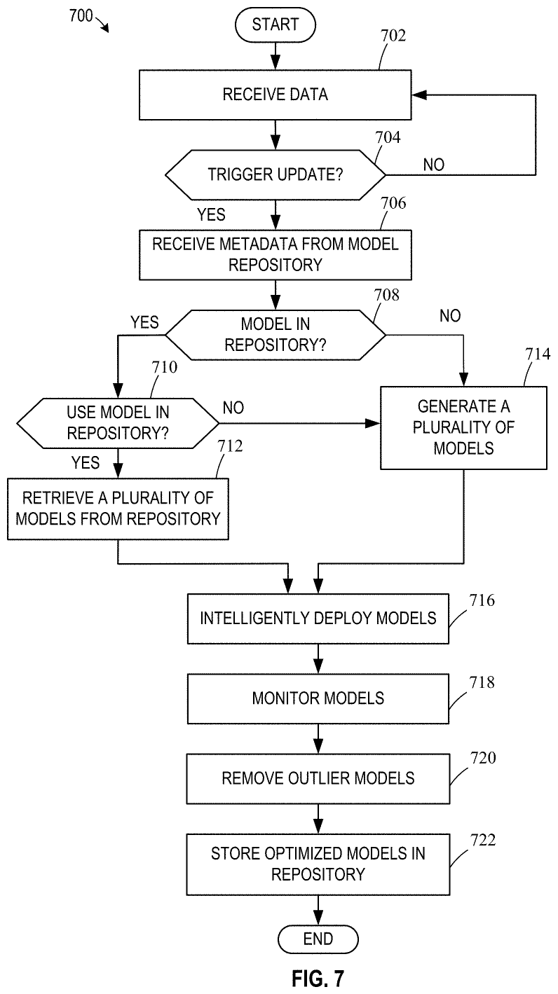

The example environmental data interface circuitry 504 is implemented by a logic circuit such as, for example, a hardware (e.g., semi-conductor based) processor. However, any other type of circuitry may additionally or alternatively be used such as, for example, one or more analog or digital circuit(s), logic circuits, programmable processor(s), application specific integrated circuit(s) (ASIC(s)), programmable logic device(s) (PLD(s)), field programmable logic device(s) (FPLD(s)), digital signal processor(s) (DSP(s)), etc. The example environmental data interface circuitry 504 is structured to communicate with the environmental sensors operating at the factory. For example, the environmental sensors may be configured to detect changes in temperature, light or shade, humidity, etc. The example environmental data interface circuitry 504 communicates with the example intelligent trigger circuitry 506. In response to the environmental data received, the example intelligent trigger circuitry 506 may start the automated model update process, which is further described in FIG. 7.

The example intelligent trigger circuitry 506 is implemented by a logic circuit such as, for example, a hardware (e.g., semi-conductor based) processor. However, any other type of circuitry may additionally or alternatively be used such as, for example, one or more analog or digital circuit(s), logic circuits, programmable processor(s), application specific integrated circuit(s) (ASIC(s)), programmable logic device(s) (PLD(s)), field programmable logic device(s) (FPLD(s)), digital signal processor(s) (DSP(s)), etc. The example intelligent trigger circuitry 506 uses four sources of information to determine if an artificial intelligence model update is to occur. The example intelligent trigger circuitry 506 is to use metric baseline information, output from the current artificial intelligence model, metadata, and/or output from artificial intelligence models operating on other production lines or produced by the other example model update controller circuitry 418. In some examples, if the example input parameters are not changed sufficiently (e.g., according to a threshold level of change) a model update may leave the artificial intelligence model unchanged.

The metric baseline is learned by the example intelligent trigger circuitry 506. The example intelligent trigger circuitry 506 averages the output from the deployed model over a time period. For example, the normal baseline of the positive rate of a fault detection use case can be learnt by the example intelligent trigger circuitry 506 by recording an average of the number of positive predictions made by the AI model over a certain amount of time.

The example intelligent trigger circuitry 506 monitors the output of the current artificial intelligence model and compares with the learnt normal baseline. For example, in the use case of detection of faulty screw driving process results, the example intelligent trigger circuitry 506 monitors how many positives (faulty) are predicted by the AI model over time and calculates the positive rate. When the example intelligent trigger circuitry 506 detects that the positive rate deviates from the normal baseline, example intelligent trigger circuitry 506 triggers the example automated model search circuitry 508 to develop new model candidates.

The example intelligent trigger circuitry 506 may use metadata. Metadata, such as equipment and/or process configurations and environmental sensor readings, is also fed into this module, so that the module knows whether the change in the metric coincides with process/equipment configuration changes or with changes in temperature or humidity in the factory. Modern factories typically have change control process where changes of configurations are logged into databases. Therefore, once the example intelligent trigger circuitry 506 detects deviation from normal baseline, the example intelligent trigger circuitry 506 sends queries to the database (e.g., the environmental database 412) where meta data is stored and investigates whether there are any updates. Alternatively, the configuration information may be stored on the local hard drive on the industrial equipment and/or controllers, and the example intelligent trigger circuitry 506 may read meta data from a hard drive. Additionally, the readings from environmental sensors can be communicated through networks in the factory to the example intelligent trigger circuitry 506.

The example intelligent trigger circuitry 506 may use the outputs from AI models running on other identical production lines that performs the same task as the production line in question. For example, when a sudden increase of positive rate is detected by the example intelligent trigger circuitry 506 on one screw driving line, the example intelligent trigger circuitry 506 checks whether its fellow screw driving lines detected a similar increase.

By monitoring outputs from the deployed AI model, example intelligent trigger circuitry 506 will activate the example automated model search circuitry 508 when a deviation from the baseline is detected. Based on the meta data (e.g., environmental data) and information from other deployed AI models described above, the example intelligent trigger circuitry 506 can determine whether the change in the metric that it has detected is a global change (other production lines also experience similar change) or a local change, and what the change is correlated with (such as a sudden increase in temperature or humidity in the factory). This judgement will then be passed onto the example intelligent deployment circuitry 510 to facilitate the self-improvement of the model deployment module.

The example automated model search circuitry 508 is implemented by a logic circuit such as, for example, a hardware (e.g., semi-conductor based) processor. However, any other type of circuitry may additionally or alternatively be used such as, for example, one or more analog or digital circuit(s), logic circuits, programmable processor(s), application specific integrated circuit(s) (ASIC(s)), programmable logic device(s) (PLD(s)), field programmable logic device(s) (FPLD(s)), digital signal processor(s) (DSP(s)), etc. The example automated model search circuitry 508 is configured to either generate new models or search for models from the artificial intelligence model repository 404 through the communication of the example data interface circuitry 502. In some examples, the automated model search circuitry 508 generates at least one new model. In other examples, the example automated model search circuitry 508 generates at least one model from at least three model types according to a model generation technique.

For a first type of model, the example automated model search circuitry 508 may generate a first candidate model that implements the same model architecture as the old model, but the model parameters are updated with newly collected data on the production line.

For a second type of model, the example automated model search circuitry 508 may generate a second candidate model that updates the hyperparameters of the old model, and/or makes some partial changes in model architecture but keeps the major component of the model architecture unchanged. An example can be the kernel function used in support vector machine (SVM) can be changed to build a new model. Another example is that when the shape or some other property of defects have changed in a defect detection use case, the final few layers of a deep neural network that was trained to detect the original defects can be changed and trained to adapt to the new defects.

For a third type of model, the example automated model search circuitry 508 may generate a third candidate model that implement a different model architecture will be generated by the model search module. For example, if the original AI model deployed is a support vector machine (SVM) based classifier, a new classifier that is based on random forest can be built. More than one candidate models with new architectures can be generated, and the number of such new models can be pre-configured. A different random seed is used for each production line for such model search.

The example automated model search circuitry 508 may use the second type of model or the third type of model because in industrial setting finding anomalous data is very challenging especially with ever-changing configurations and environmental settings. It is also hard to reproduce such anomalies and use them for training, especially in the initial stages of model deployment. When there is a new type of anomalous data detected, the existing model(s) are updated to account for new defects, or a new model is added to detect the new type of anomaly. This is achieved using one of the second type of model from above or the third type of model from above, amounting to a scalable self-learning system.

Alternatively, the example automated model search circuitry 508 may select a model from the example model repository 404. Each AI model that has been deployed previously is stored in the example artificial intelligence model repository 404 with some metadata, such as the production line that it was deployed on, the equipment/process configuration of that particular production line, the model performance (e.g., prediction accuracy), the environmental conditions in the factory (e.g., temperature and humidity) when the model was running. A similarity score can be computed using the meta data between the models of the example artificial intelligence model repository 404 and the to-be-updated AI model in question. The AI models in the example artificial intelligence model repository 404 can be narrowed down to the ones that have the highest similarity scores and then based on their model performance in the past, example automated model search circuitry 508 may select the model candidates out of the plurality of models in the example artificial intelligence model repository 404.

The example intelligent deployment circuitry 510 is implemented by a logic circuit such as, for example, a hardware (e.g., semi-conductor based) processor. However, any other type of circuitry may additionally or alternatively be used such as, for example, one or more analog or digital circuit(s), logic circuits, programmable processor(s), application specific integrated circuit(s) (ASIC(s)), programmable logic device(s) (PLD(s)), field programmable logic device(s) (FPLD(s)), digital signal processor(s) (DSP(s)), etc. The example intelligent deployment circuitry 510 is to deploy the artificial intelligence models. In the initial deployment phase, example intelligent deployment circuitry 510 first runs all the model candidates in parallel and uses an algorithm to determine a single output. The algorithm starts as a majority vote mechanism or calculation of average giving each model the same weight. The example intelligent deployment circuitry 510 improves itself over time by detecting outlier models from the model candidates. If the predictions from one or some model candidates are frequently different from the rest majority, then the weights for those outlier models are gradually reduced by the model deployment module.

If the change that has triggered the model update is a global change (i.e., occurred on more than one production lines), the example intelligent deployment circuitry 510 then improves itself over time by collaborating with the example intelligent deployment circuitry 510 running on the other identical production lines (e.g., example intelligent deployment circuitry running on the other example model update controller circuitry 418). The idea is that the multiple identical production lines should converge to a similar new baseline (e.g., predicted positive rate) after a global change that has taken place on all of them. Therefore, the example intelligent deployment circuitry 510 should gradually weigh more heavily on the models that produce a metric value that is closer to the global baseline of that metric. An example of convergence is shown in conjunction with FIG. 9.

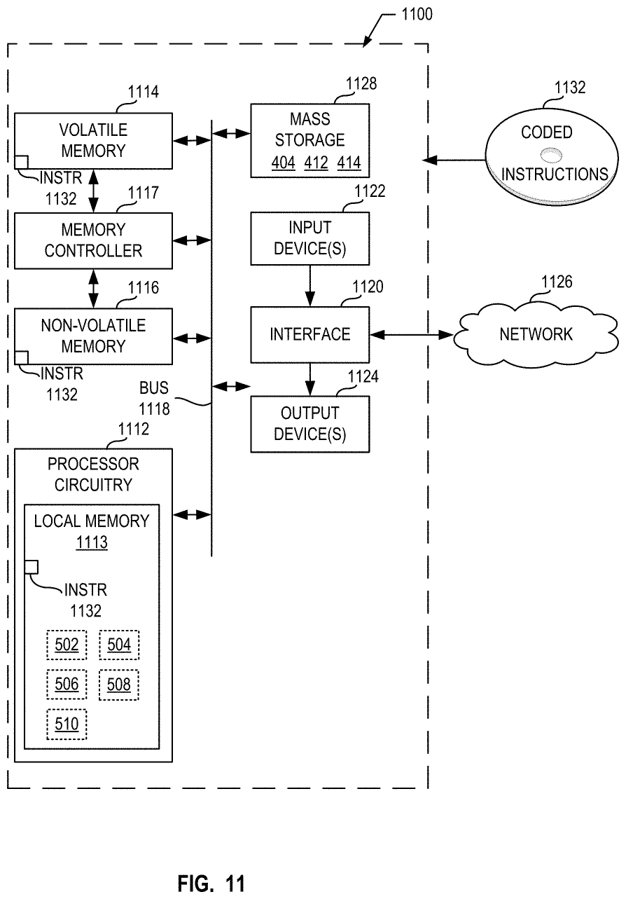

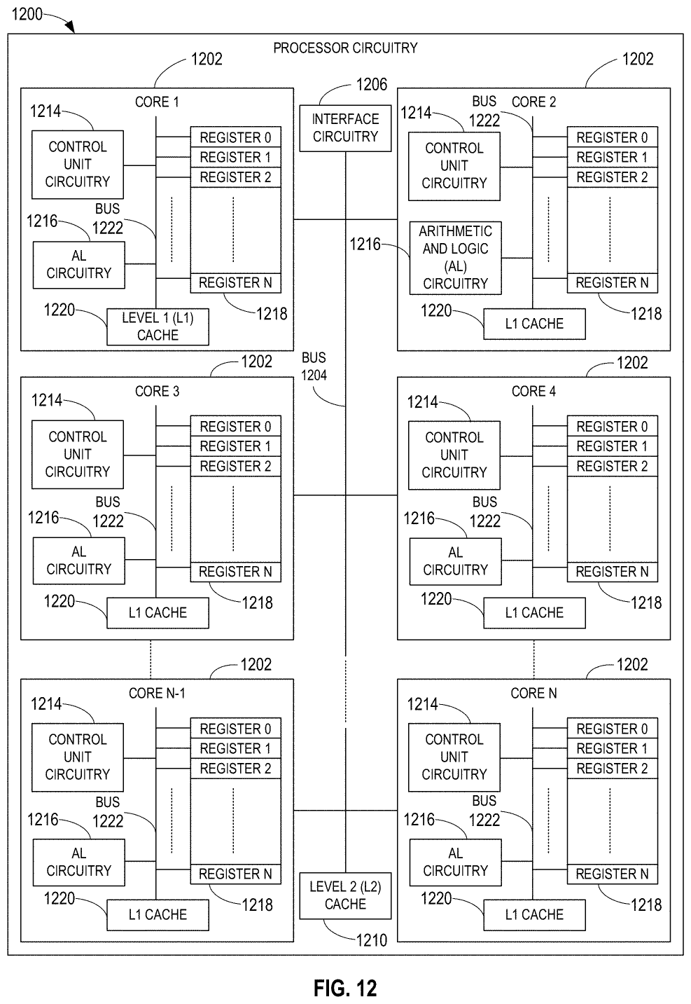

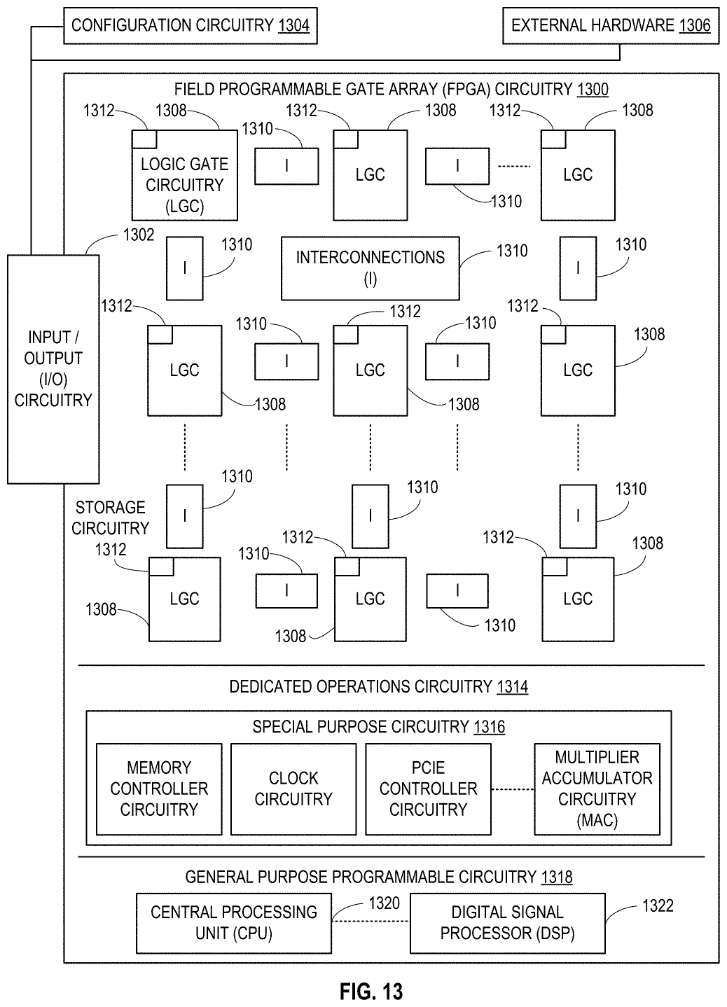

In some examples, the apparatus includes means for triggering an automated model update process. For example, the means for triggering an automated model update process may be implemented by intelligent trigger circuitry 506. In some examples, the intelligent trigger circuitry 506 may be implemented by machine executable instructions such as that implemented by at least blocks 702, 704 of FIG. 7 executed by processor circuitry, which may be implemented by the example processor circuitry 1112 of FIG. 11, the example processor circuitry 1200 of FIG. 12, and/or the example Field Programmable Gate Array (FPGA) circuitry 1300 of FIG. 13. In other examples, the intelligent trigger circuitry 506 is implemented by other hardware logic circuitry, hardware implemented state machines, and/or any other combination of hardware, software, and/or firmware. For example, the intelligent trigger circuitry 506 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the apparatus includes means for generating a plurality of candidate artificial intelligence models. For example, the means for generating a plurality of candidate artificial intelligence models may be implemented by automated model search circuitry 508. In some examples, the automated model search circuitry 508 may be implemented by machine executable instructions such as that implemented by at least blocks 708, 710, 714 of FIG. 7 executed by processor circuitry, which may be implemented by the example processor circuitry 1112 of FIG. 11, the example processor circuitry 1200 of FIG. 12, and/or the example Field Programmable Gate Array (FPGA) circuitry 1300 of FIG. 13. In other examples, the intelligent trigger circuitry 506 is implemented by other hardware logic circuitry, hardware implemented state machines, and/or any other combination of hardware, software, and/or firmware. For example, intelligent trigger circuitry 506 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the apparatus includes means for to improve prediction performance over time. For example, the means for to improve prediction performance over time may be implemented by intelligent deployment circuitry 510. In some examples, the intelligent deployment circuitry 510 may be implemented by machine executable instructions such as that implemented by at least blocks 716, 718, 720, 722 of FIG. 7 executed by processor circuitry, which may be implemented by the example processor circuitry 1112 of FIG. 11, the example processor circuitry 1200 of FIG. 12, and/or the example Field Programmable Gate Array (FPGA) circuitry 1300 of FIG. 13. In other examples, the intelligent deployment circuitry 510 is implemented by other hardware logic circuitry, hardware implemented state machines, and/or any other combination of hardware, software, and/or firmware. For example, intelligent deployment circuitry 510 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

While an example manner of implementing the model update controller circuitry 410 of FIG. 4 is illustrated in FIG. 5, one or more of the elements, processes, and/or devices illustrated in FIG. 5 may be combined, divided, re-arranged, omitted, eliminated, and/or implemented in any other way. Further, the example data interface circuitry 502, an example environmental data interface circuitry 504, example intelligent trigger circuitry 506, example automated model search circuitry 508, and example intelligent deployment circuitry 510 and/or, more generally, the example model update controller circuitry 410 of FIG. 4, may be implemented by hardware, software, firmware, and/or any combination of hardware, software, and/or firmware. Thus, for example, any of the example data interface circuitry 502, example environmental data interface circuitry 504, example intelligent trigger circuitry 506, example automated model search circuitry 508, and example intelligent deployment circuitry 510 and/or, more generally, the example model update controller circuitry 410, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). When reading any of the apparatus or system claims of this patent to cover a purely software and/or firmware implementation, at least one of the example data interface circuitry 502, example environmental data interface circuitry 504, example intelligent trigger circuitry 506, example automated model search circuitry 508, and/or the example intelligent deployment circuitry 510 is/are hereby expressly defined to include a non-transitory computer readable storage device or storage disk such as a memory, a digital versatile disk (DVD), a compact disk (CD), a Blu-ray disk, etc., including the software and/or firmware. Further still, the example model update controller circuitry 410 of FIG. 4 may include one or more elements, processes, and/or devices in addition to, or instead of, those illustrated in FIG. 5, and/or may include more than one of any or all of the illustrated elements, processes and devices.

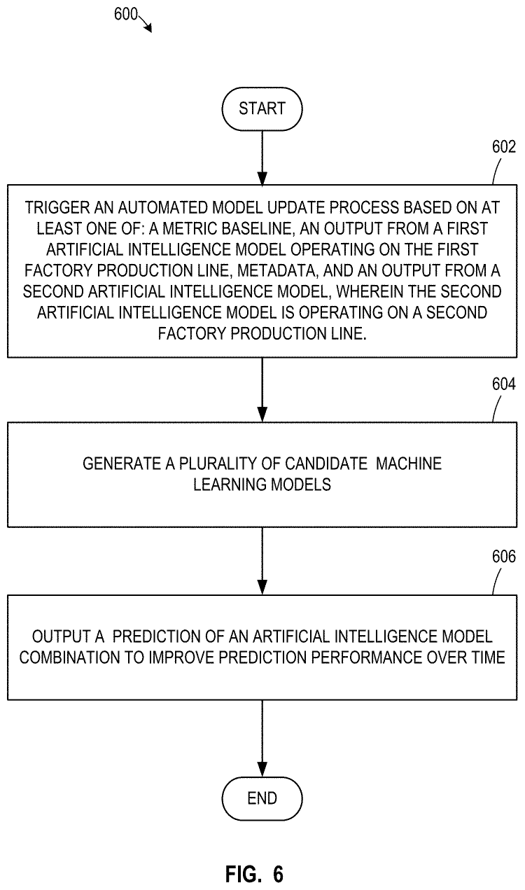

A flowchart representative of example hardware logic circuitry, machine readable instructions, hardware implemented state machines, and/or any combination thereof for implementing the model update controller circuitry 410 of FIG. 4 is shown in FIG. 6 and FIG. 7. The machine readable instructions may be one or more executable programs or portion(s) of an executable program for execution by processor circuitry, such as the processor circuitry 1112 shown in the example processor platform 1100 discussed below in connection with FIG. 11 and/or the example processor circuitry discussed below in connection with FIGS. 12 and/or 13. The program may be embodied in software stored on one or more non-transitory computer readable storage media such as a CD, a floppy disk, a hard disk drive (HDD), a DVD, a Blu-ray disk, a volatile memory (e.g., Random Access Memory (RAM) of any type, etc.), or a non-volatile memory (e.g., FLASH memory, an HDD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN) gateway that may facilitate communication between a server and an endpoint client hardware device). Similarly, the non-transitory computer readable storage media may include one or more mediums located in one or more hardware devices. Further, although the example program is described with reference to the flowchart illustrated in FIGS. 6-7, many other methods of implementing the example model update controller circuitry 410 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU), etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 6-7 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium and non-transitory computer readable storage medium is expressly defined to include any type of computer readable storage device and/or storage disk and to exclude propagating signals and to exclude transmission media.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 6 is a flowchart representative of example machine readable instructions and/or example operations 600 that may be executed and/or instantiated by processor circuitry to output candidate model combinations based on a model update process. The machine readable instructions and/or operations 600 of FIG. 6 begin at block 602, at which the example intelligent trigger circuitry 506 triggers an automated model update process based on at least one of four sources of information. For example, the example intelligent trigger circuitry 506 may trigger an automated mode update process based on a metric baseline data, metadata including environmental data, artificial intelligence model data, or artificial intelligence model data from other production lines.

At block 604, the example automated model search circuitry 508 generates a plurality of candidate machine learning models. For example, the example automated model search circuitry 508 may generate a plurality of candidate machine learning models by searching an artificial intelligence repository of machine learning models or by generating at least three types of models. In some examples, the example automated model search circuitry 508 may generate a first new artificial intelligence model that implements the model architecture of the first artificial intelligence model operating on the first production line, but includes updated model parameters based on newly collected data or may generate a second new artificial intelligence model that implements a similar model architecture of the first artificial intelligence model operating on the first production line, but includes hyperparameter updates or may generate a third new artificial intelligence model that implements a new model architecture, the new model architecture not based on the first artificial intelligence model operating on the first production line.

At block 606, the example intelligent deployment circuitry 510 outputs a prediction of model combinations to improve prediction performance over time. For example, the intelligent deployment circuitry 510 may output a prediction of model combinations to improve prediction performance over time by monitoring the plurality of models produced, removing outliers, and/or storing models that are performing near a threshold of quality. The example instructions 600 end. In some examples, the example instructions 600 return to the block 602, as the process is repeats (e.g., is always occurring).

FIG. 7 is a flowchart representative of example machine readable instructions and/or example operations 700 that may be executed and/or instantiated by processor circuitry to output candidate model combinations based on a model update process. The machine readable instructions and/or operations 700 of FIG. 7 begin at block 702, at which the example intelligent trigger circuitry 506 receives at least one of four sources of data. For example, the example intelligent trigger circuitry 506 may receive at least one of four sources of data by accessing either a metric baseline, an output from a first artificial intelligence model operating on the first factory production line, metadata, or an output from a second artificial intelligence model, wherein the second artificial intelligence model is operating on a second factory production line. Control flows to block 704.

At block 704, the intelligent trigger circuitry 506 determines to trigger an update. For example, the intelligent trigger circuitry 506 may determine to trigger an update in response to a deviation from a metric baseline. For example, the intelligent trigger circuitry 506 may determine to trigger an update in response to an output from a first artificial intelligence model operating on the first factory production line, such as an indication that the accuracy of the first artificial intelligence model is inaccurate in predicting errors in a manufacturing process. For example, the intelligent trigger circuitry 506 may determine to trigger an update in response to metadata, such as at least one of environmental sensor readings, equipment configurations, and process configurations. For example, the intelligent trigger circuitry 506 may determine to trigger an update in response to an output from a second artificial intelligence model, wherein the second artificial intelligence model is operating on a second factory production line, such as an indication that the accuracy of the second artificial intelligence model is inaccurate in predicting errors in a manufacturing process.

For example, the example intelligent trigger circuitry 506 may determine to not trigger an update (e.g., “NO”). Control flows to block 702 for the intelligent trigger circuitry 506 to receive at least one of the four sources of data. For example, the example intelligent trigger circuitry 506 may determine to trigger an update (e.g., “YES”). Control flows to block 706.

At block 706, the example data interface circuitry 502 receives metadata from the example model repository 404. For example, the example data interface circuitry 502 may receive metadata from the example model repository 404 by accessing metadata corresponding to different artificial intelligence models in the example model repository 404. Control flows to block 708.

At block 708, the example automated model search circuitry 508 determines if a similar model is in the model repository 404. For example, the example automated model search circuitry may determine a model is in the model repository 404 by determining if there are any models in the example model repository 404. For example, the example automated model search circuitry 508 may determine a model is in the model repository 404 (e.g., “YES”). Control flows to block 710. For example, the example automated model search circuitry 508 may determine there is not a model in the model repository 404 (e.g., “NO”). Control flows to block 714.

At block 710, the example automated model search circuitry 508 determines to use the model in the model repository 404. For example, the example automated model search circuitry 508 may determine to use a model in the model repository based on a similarity score corresponding to the metadata between artificial intelligence models in the model repository 404 and the conditions on the factory production line. For example, the example automated model search circuitry 508 may determine to use an artificial intelligence model is in the model repository 404 (e.g., “YES”). Control flows to block 712. For example, the example automated model search circuitry 508 may determine to not use an artificial intelligence model in the model repository 404 (e.g., “NO”). Control flows to block 714.

At block 712, the example automated search circuitry 508 retrieves a plurality of models from the model repository 404. For example, the example automated search circuitry 508 may retrieve a plurality of models from the model repository 404 based on a similarity score between the meta data and the current factory production line. In some examples, the example automated search circuitry 508 may retrieve a plurality of models from the model repository 404 based on performance scores of the models. Control flows to block 716.

At block 714, the example automated search circuitry 508 generates a plurality of models. For example, the example automated model search circuitry 508 may generate at plurality of models in response to a lack of models in the example model repository 404 or a lack of similar (e.g., based on metadata) models in the example a model repository 404. For example, there may not be a model that is tuned for certain environmental conditions, such as a temperature fluctuation of ten degrees after the factory line is at full production, so the example automated model search circuitry 508 may generate a plurality of models and store the specific metadata corresponding to the conditions at the time the model was generated. In some examples, the plurality of models is at least two (2). The output data from the plurality of models (e.g., at least two) are used to determine an average faulty rate and to remove outlier models. Control blocks to block 716.

At block 716, the example intelligent deployment circuitry 510 intelligently deploys the artificial intelligence models. For example, the example intelligent deployment circuitry 510 may intelligently deploy the artificial intelligence models by running (e.g., deploying) the candidate models in parallel and determining a single output that incorporates data from the plurality of models based on an algorithm. In some examples, the algorithm is a majority vote mechanism or an average calculation which gives the candidate models a similar (e.g., same, identical) weight. Control flows to block 718.

At block 718, the example intelligent deployment circuitry 510 monitors the candidate models. For example, the example intelligent deployment circuitry 510 may monitor the candidate models by determining the output of the plurality of models. As time elapses, the weight assigned to a particular candidate model in the plurality of models (e.g., model ensemble) may either increase or decrease based on the output of the particular candidate model. Control flows to block 720.

At block 720, the example intelligent deployment circuitry 510 removes outlier models. For example, the example intelligent deployment circuitry 510 may remove outlier models by determining a model is either predicting an above average faulty rate or a below average faulty rate. For example, if the true faulty rate is five percent (5%), a model that consistently predicts a faulty rate of twenty percent (20%) which is above the average faulty rate, may be removed from the plurality of models (e.g., ensemble of models). Control flows to block 722.

At block 722, the example intelligent deployment circuitry 510 stores optimized models in the model repository 404. For example, the example intelligent deployment circuitry 510 may store a candidate model that performs above a threshold in the example model repository 404 with the metadata corresponding to the factory production line that is monitored by the optimized candidate model. The optimized candidate model is stored and may be selected by the example automated model search circuitry 508 at a later time. The example instructions 700 end.

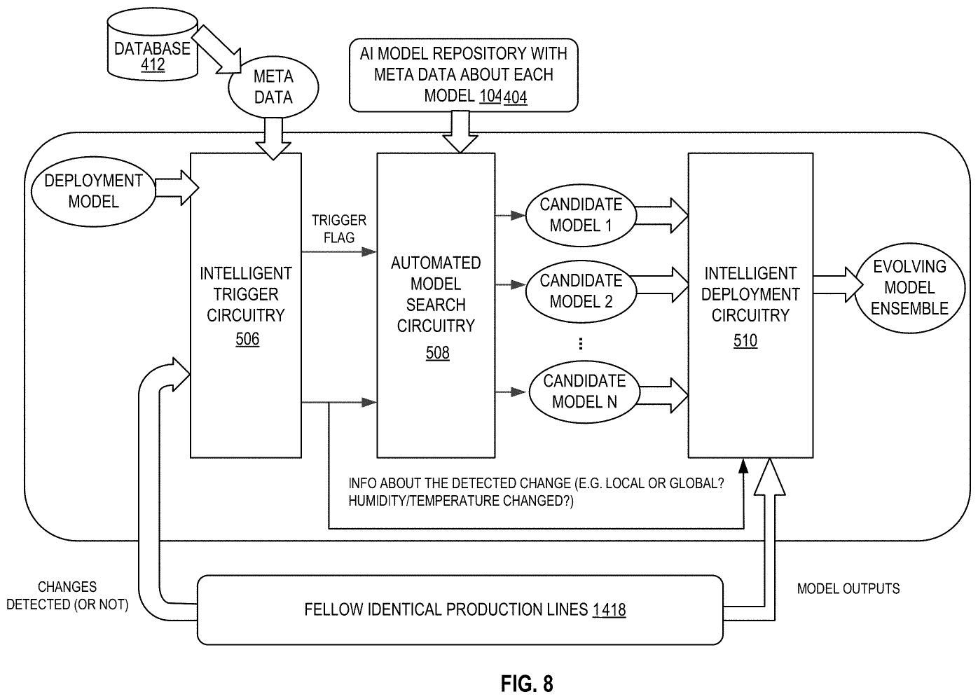

FIG. 8 is a model process data flow diagram. In the example of FIG. 8, the example intelligent trigger circuitry 506, the example automated model search circuitry 508, and the example intelligent deployment circuitry 510 work to automate the development and/or the deployment of machine learning models in, for example, a factory environment. For example, machine learning models that may be deployed in edge infrastructure such as the edge infrastructure described in conjunction with FIGS. 1-3. The artificial intelligence models (e.g., machine learning models) use data generated by factories or other data sources (e.g., industrial data sources, commercial data sources, etc.). For example, manufacturing processes in factories are subject to environmental variations.

In the example of FIG. 8, the example intelligent trigger circuitry 506 accesses the current deployment model, metadata from the example environmental database 412, and output data from the models operating on the fellow identical production lines as generated by the other example model update controller circuitry 418. In response to the four sources of data, the example intelligent trigger circuitry 506 triggers the update process. The example automated model search circuitry 508 generates the candidate models (e.g., the candidate model 1, the example candidate model 2, other candidate models that are not shown, and the example candidate model n). The example automated model search circuitry 508 generates the candidate models or retrieves similar candidate models from the artificial intelligence model repository 404. The example intelligent deployment circuitry 510 deploys the evolving ensemble of models received from the example automated model search circuitry 508. The example intelligent deployment circuitry 510 may monitor the behavior and accuracy of the deployed model as time elapses, and in response to poor performing models (e.g., according to a threshold), remove outlier models and store better performing models (e.g., according to a threshold). In some examples, the better performing models are labeled and saved for future use. The evolving model ensemble may be used as the deployment model when the process repeats.

FIG. 9 is an extended example of the monitoring performed by the example intelligent deployment circuitry. In this example, there are 3 robots performing the same screw driving task in a factory (e.g., Robot A, Robot B, and Robot C). In the example of FIG. 9, each robot gets 3 model candidates to predict if a screw driving process is faulty or not faulty. For example, Robot A gets model candidate A1, model candidate A2, and model candidate A3. The example intelligent deployment circuitry on each robot keeps track of the prediction results from the model candidates. In some examples, the model candidates A1, A2, and A3 are labeled and saved for future use. For example, the labeled model A1 may be stored in the example artificial intelligence model repository 404 (shown in FIG. 4 or FIG. 8) as a template for building the next candidate model. The average faulty rate from the 3 robots is 1%. Therefore, model A1 will be weighed more by Robot A, model B3 by Robot B, and model C1 by Robot C in the majority vote algorithm.

The evolving ensemble of model candidates (the weight of each model candidate changing over time) is the new AI model deployed to replace the old AI model. The ensemble is viewed as one model, and if later on the ensemble needs to be updated, one new set of model candidates will be generated instead of multiple sets. In this way the memory and storage space needed for models can be reduced. The ensemble is to improve weaker models to produce higher performance models, where a higher performance model may be measured by a metric such as accuracy.

Example column 902 refers to the field representing the model candidates. Example column 904, 906, 908, 910, and 912, represent the prediction of the model candidate at a time instance. For example, column 904 is the prediction at a first time. In the example of FIG. 9, the prediction is either “ok” (e.g., okay, satisfactory, good, etc.) or “nok” (e.g., not okay, unsatisfactory, bad). The example faulty rate (e.g., column 914) is the prediction of how the screw driving assembly line is producing errors. For example, a faulty rate of 3% means that there are defects in the manufacturing process around 3%.

Example row 916 refers to the model candidate A1, as example row 918 refers to the model candidate A2, while example row 920 refers to the model candidate A3. The average faulty rate (e.g., the majority vote faulty rate) for Robot A is represented by row 922. Example row 924 refers to the average faulty rate for Robot B and example row 926 refers to average faulty rate for Robot C.

At the first time instance (e.g., column 904) for the model candidate A1 in row 916, the prediction is “nok” (e.g., not okay) for the screw driving assembly line. However, as more time elapses, such as at a second time instance (e.g., column 906), the prediction is “ok” (e.g., okay) for the screw driving assembly line. As more time elapses the prediction stabilizes to a faulty rate of 0.9% (e.g., column 914) for the screw driving assembly line. The second model candidate A2 in row 918 predicts a faulty rate of the screw driving assembly line as 3%, while the third model candidate A3 in row 920 predicts a faulty rate of the screw driving assembly line as 0.4%. According to an average of the faulty rate of a corresponding screw driving assembly line, the true (e.g., accurate, reliable, agreed-upon) faulty rate is around 1%. Robot B predicts a faulty rate of 1.2% as shown in row 924, while Robot C predicts a faulty rate of 0.8% as shown in row 926. Robot A uses the faulty rate prediction from Robot B and Robot C to remove the outlier model A3 that predicts a faulty rate of the screwdriving assembly line at 0.4% and the outlier model A2 that predicts a faulty rate of the screwdriving assemble line at 3%. The model A3 is predicting lower positive rates than the true positive rate, and the factory is producing more errors than the model A3 predicted. The model A2 is predicting higher positive rates than the true positive rate, as the factory is producing less errors than the model A2 predicted. Either model (e.g., A2 or A3) is inefficient. In the example of FIG. 9, the model A1 which produces 0.9% faulty rate is stored in the artificial intelligence model repository 404 of FIG. 4.

Example of predictions from candidate models on multiple different robots that perform the same task. Faulty rate is measured over a certain time period for each model candidate. The majority vote result at each time step for each robot is used by the example intelligent deployment circuitry as the prediction result at each time step for each robot. The three robots communicate with the other robots and determine the average faulty rate (1% in this example) for the task after a global change has triggered the model update process on the three robots. Then the example intelligent deployment circuitry on the individual robots will gradually give more weight to the model candidate that matches better with the new global average faulty rate.

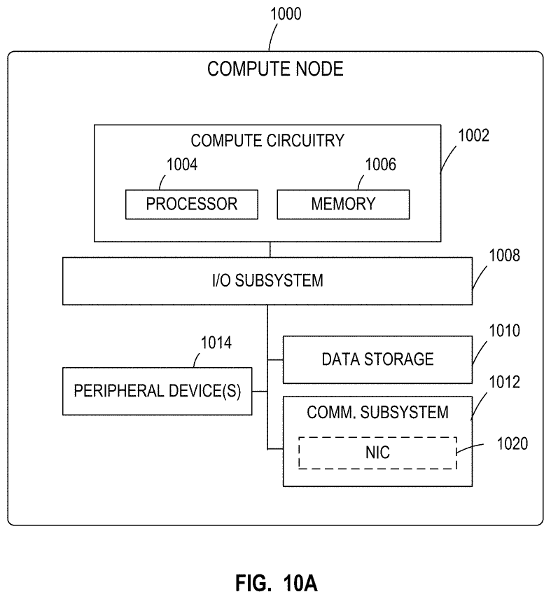

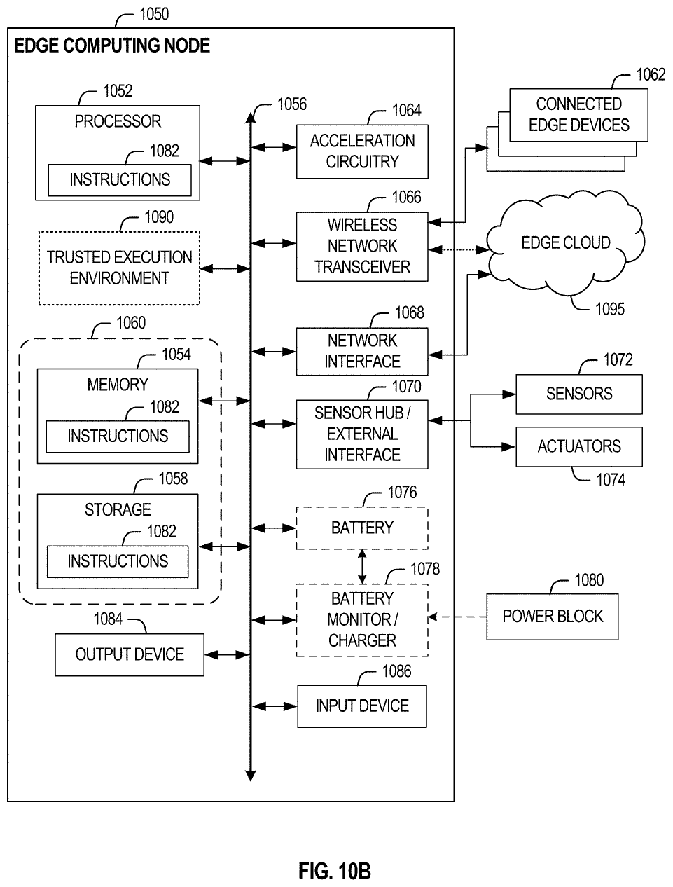

In some examples, FIG. 9 is an example management console (e.g., visual display, monitoring station, instrument panel, dashboard, etc.) wherein a biological entity such as a human being may track the evolving ensemble of models. For example, the human being (engineer, worker, foreman, data scientist, etc.) may track the performance of the models and intervene (e.g., adjust the model) in response to a determination made by the human being. In these examples, the different characteristics (e.g., configurations) of the model may be displayed to a person. In some examples, the different characteristics (e.g., configurations) of the model may be displayed to the human. In some examples, the machine learning algorithm is to automatically track the performance of the models without intervention from a human. The example management console may be visible either locally (e.g., at the factory) or remotely (e.g., at a data processing center). In some examples, the example management console may be implemented by an IoT device (e.g., wireless cellphone, a stand-alone appliance, etc.) as described in FIGS. 10A and 10B.

In some examples, the candidate models may be profile configured, such that a first factory uses the candidate models while a second factory may with a different profile may tweak the models.

In further examples, any of the compute nodes or devices discussed with reference to the present edge computing systems and environment may be fulfilled based on the components depicted in FIGS. 10A and 10B. Respective edge compute nodes may be embodied as a type of device, appliance, computer, or other “thing” capable of communicating with other edge, networking, or endpoint components. For example, an edge compute device may be embodied as a personal computer, server, smartphone, a mobile compute device, a smart appliance, an in-vehicle compute system (e.g., a navigation system), a self-contained device having an outer case, shell, etc., or other device or system capable of performing the described functions.

In the simplified example depicted in FIG. 10A, an edge compute node 1000 includes a compute engine (also referred to herein as “compute circuitry”) 1002, an input/output (I/O) subsystem 1008, data storage 1010, a communication circuitry subsystem 1012, and, optionally, one or more peripheral devices 1014. In other examples, respective compute devices may include other or additional components, such as those typically found in a computer (e.g., a display, peripheral devices, etc.). Additionally, in some examples, one or more of the illustrative components may be incorporated in, or otherwise form a portion of, another component.

The compute node 1000 may be embodied as any type of engine, device, or collection of devices capable of performing various compute functions. In some examples, the compute node 1000 may be embodied as a single device such as an integrated circuit, an embedded system, a field-programmable gate array (FPGA), a system-on-a-chip (SOC), or other integrated system or device. In the illustrative example, the compute node 1000 includes or is embodied as a processor 1004 and a memory 1006. The processor 1004 may be embodied as any type of processor capable of performing the functions described herein (e.g., executing an application). For example, the processor 1004 may be embodied as a multi-core processor(s), a microcontroller, a processing unit, a specialized or special purpose processing unit, or other processor or processing/controlling circuit.

In some examples, the processor 1004 may be embodied as, include, or be coupled to an FPGA, an application specific integrated circuit (ASIC), reconfigurable hardware or hardware circuitry, or other specialized hardware to facilitate performance of the functions described herein. Also in some examples, the processor 1004 may be embodied as a specialized x-processing unit (xPU) also known as a data processing unit (DPU), infrastructure processing unit (IPU), or network processing unit (NPU). Such an xPU may be embodied as a standalone circuit or circuit package, integrated within an SOC, or integrated with networking circuitry (e.g., in a SmartNIC, or enhanced SmartNIC), acceleration circuitry, storage devices, or AI hardware (e.g., GPUs or programmed FPGAs). Such an xPU may be designed to receive programming to process one or more data streams and perform specific tasks and actions for the data streams (such as hosting microservices, performing service management or orchestration, organizing or managing server or data center hardware, managing service meshes, or collecting and distributing telemetry), outside of the CPU or general purpose processing hardware. However, it will be understood that a xPU, a SOC, a CPU, and other variations of the processor 1004 may work in coordination with each other to execute many types of operations and instructions within and on behalf of the compute node 1000.

The memory 1006 may be embodied as any type of volatile (e.g., dynamic random access memory (DRAM), etc.) or non-volatile memory or data storage capable of performing the functions described herein. Volatile memory may be a storage medium that requires power to maintain the state of data stored by the medium. Non-limiting examples of volatile memory may include various types of random access memory (RAM), such as DRAM or static random access memory (SRAM). One particular type of DRAM that may be used in a memory module is synchronous dynamic random access memory (SDRAM).

In an example, the memory device is a block addressable memory device, such as those based on NAND or NOR technologies. A memory device may also include a three dimensional crosspoint memory device (e.g., Intel® 3D XPoint™ memory), or other byte addressable write-in-place nonvolatile memory devices. The memory device may refer to the die itself and/or to a packaged memory product. In some examples, 3D crosspoint memory (e.g., Intel® 3D XPoint™ memory) may comprise a transistor-less stackable cross point architecture in which memory cells sit at the intersection of word lines and bit lines and are individually addressable and in which bit storage is based on a change in bulk resistance. In some examples, all or a portion of the memory 1006 may be integrated into the processor 1004. The memory 1006 may store various software and data used during operation such as one or more applications, data operated on by the application(s), libraries, and drivers.

The compute circuitry 1002 is communicatively coupled to other components of the compute node 1000 via the I/O subsystem 1008, which may be embodied as circuitry and/or components to facilitate input/output operations with the compute circuitry 1002 (e.g., with the processor 1004 and/or the main memory 1006) and other components of the compute circuitry 1002. For example, the I/O subsystem 1008 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some examples, the I/O subsystem 1008 may form a portion of a system-on-a-chip (SoC) and be incorporated, along with one or more of the processor 1004, the memory 1006, and other components of the compute circuitry 1002, into the compute circuitry 1002.

The one or more illustrative data storage devices 1010 may be embodied as any type of devices configured for short-term or long-term storage of data such as, for example, memory devices and circuits, memory cards, hard disk drives, solid-state drives, or other data storage devices. Individual data storage devices 1010 may include a system partition that stores data and firmware code for the data storage device 1010. Individual data storage devices 1010 may also include one or more operating system partitions that store data files and executables for operating systems depending on, for example, the type of compute node 1000.

The communication circuitry 1012 may be embodied as any communication circuit, device, or collection thereof, capable of enabling communications over a network between the compute circuitry 1002 and another compute device (e.g., an edge gateway of an implementing edge computing system). The communication circuitry 1012 may be configured to use any one or more communication technology (e.g., wired or wireless communications) and associated protocols (e.g., a cellular networking protocol such a 3GPP 4G or 5G standard, a wireless local area network protocol such as IEEE 802.11/Wi-Fi®, a wireless wide area network protocol, Ethernet, Bluetooth®, Bluetooth Low Energy, a IoT protocol such as IEEE 802.15.4 or ZigBee®, low-power wide-area network (LPWAN) or low-power wide-area (LPWA) protocols, etc.) to effect such communication.

The illustrative communication circuitry 1012 includes a network interface controller (NIC) 1020, which may also be referred to as a host fabric interface (HFI). The NIC 1020 may be embodied as one or more add-in-boards, daughter cards, network interface cards, controller chips, chipsets, or other devices that may be used by the compute node 1000 to connect with another compute device (e.g., an edge gateway node). In some examples, the NIC 1020 may be embodied as part of a system-on-a-chip (SoC) that includes one or more processors, or included on a multichip package that also contains one or more processors. In some examples, the NIC 1020 may include a local processor (not shown) and/or a local memory (not shown) that are both local to the NIC 1020. In such examples, the local processor of the NIC 1020 may be capable of performing one or more of the functions of the compute circuitry 1002 described herein. Additionally, or alternatively, in such examples, the local memory of the NIC 1020 may be integrated into one or more components of the client compute node at the board level, socket level, chip level, and/or other levels.

Additionally, in some examples, a respective compute node 1000 may include one or more peripheral devices 1014. Such peripheral devices 1014 may include any type of peripheral device found in a compute device or server such as audio input devices, a display, other input/output devices, interface devices, and/or other peripheral devices, depending on the particular type of the compute node 1000. In further examples, the compute node 1000 may be embodied by a respective edge compute node (whether a client, gateway, or aggregation node) in an edge computing system or like forms of appliances, computers, subsystems, circuitry, or other components.

In a more detailed example, FIG. 10B illustrates a block diagram of an example of components that may be present in an edge computing node 1050 for implementing the techniques (e.g., operations, processes, methods, and methodologies) described herein. This edge computing node 1050 provides a closer view of the respective components of node 1000 when implemented as or as part of a computing device (e.g., as a mobile device, a base station, server, gateway, etc.). The edge computing node 1050 may include any combinations of the hardware or logical components referenced herein, and it may include or couple with any device usable with an edge communication network or a combination of such networks. The components may be implemented as integrated circuits (ICs), portions thereof, discrete electronic devices, or other modules, instruction sets, programmable logic or algorithms, hardware, hardware accelerators, software, firmware, or a combination thereof adapted in the edge computing node 1050, or as components otherwise incorporated within a chassis of a larger system.

The edge computing device 1050 may include processing circuitry in the form of a processor 1052, which may be a microprocessor, a multi-core processor, a multithreaded processor, an ultra-low voltage processor, an embedded processor, an xPU/DPU/IPU/NPU, special purpose processing unit, specialized processing unit, or other known processing elements. The processor 1052 may be a part of a system on a chip (SoC) in which the processor 1052 and other components are formed into a single integrated circuit, or a single package, such as the Edison™ or Galileo™ SoC boards from Intel Corporation, Santa Clara, Calif. As an example, the processor 1052 may include an Intel® Architecture Core™ based CPU processor, such as a Quark™, an Atom™, an i3, an i5, an i7, an i9, or an MCU-class processor, or another such processor available from Intel®. However, any number other processors may be used, such as available from Advanced Micro Devices, Inc. (AMD®) of Sunnyvale, Calif., a MIPS®-based design from MIPS Technologies, Inc. of Sunnyvale, Calif., an ARM®-based design licensed from ARM Holdings, Ltd. or a customer thereof, or their licensees or adopters. The processors may include units such as an A5-A13 processor from Apple® Inc., a Snapdragon™ processor from Qualcomm® Technologies, Inc., or an OMAP™ processor from Texas Instruments, Inc. The processor 1052 and accompanying circuitry may be provided in a single socket form factor, multiple socket form factor, or a variety of other formats, including in limited hardware configurations or configurations that include fewer than all elements shown in FIG. 10B.

The processor 1052 may communicate with a system memory 1054 over an interconnect 1056 (e.g., a bus). Any number of memory devices may be used to provide for a given amount of system memory. As examples, the memory 1054 may be random access memory (RAM) in accordance with a Joint Electron Devices Engineering Council (JEDEC) design such as the DDR or mobile DDR standards (e.g., LPDDR, LPDDR2, LPDDR3, or LPDDR4). In particular examples, a memory component may comply with a DRAM standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces. In various implementations, the individual memory devices may be of any number of different package types such as single die package (SDP), dual die package (DDP) or quad die package (Q17P). These devices, in some examples, may be directly soldered onto a motherboard to provide a lower profile solution, while in other examples the devices are configured as one or more memory modules that in turn couple to the motherboard by a given connector. Any number of other memory implementations may be used, such as other types of memory modules, e.g., dual inline memory modules (DIMMs) of different varieties including but not limited to microDIMMs or MiniDIMMs.

To provide for persistent storage of information such as data, applications, operating systems and so forth, a storage 1058 may also couple to the processor 1052 via the interconnect 1056. In an example, the storage 1058 may be implemented via a solid-state disk drive (SSDD). Other devices that may be used for the storage 1058 include flash memory cards, such as Secure Digital (SD) cards, microSD cards, eXtreme Digital (XD) picture cards, and the like, and Universal Serial Bus (USB) flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

In low power implementations, the storage 1058 may be on-die memory or registers associated with the processor 1052. However, in some examples, the storage 1058 may be implemented using a micro hard disk drive (HDD). Further, any number of new technologies may be used for the storage 1058 in addition to, or instead of, the technologies described, such resistance change memories, phase change memories, holographic memories, or chemical memories, among others.

The components may communicate over the interconnect 1056. The interconnect 1056 may include any number of technologies, including industry standard architecture (ISA), extended ISA (EISA), peripheral component interconnect (PCI), peripheral component interconnect extended (PCIx), PCI express (PCIe), or any number of other technologies. The interconnect 1056 may be a proprietary bus, for example, used in an SoC based system. Other bus systems may be included, such as an Inter-Integrated Circuit (I2C) interface, a Serial Peripheral Interface (SPI) interface, point to point interfaces, and a power bus, among others.

The interconnect 1056 may couple the processor 1052 to a transceiver 1066, for communications with the connected edge devices 1062. The transceiver 1066 may use any number of frequencies and protocols, such as 2.4 Gigahertz (GHz) transmissions under the IEEE 802.15.4 standard, using the Bluetooth® low energy (BLE) standard, as defined by the Bluetooth® Special Interest Group, or the ZigBee® standard, among others. Any number of radios, configured for a particular wireless communication protocol, may be used for the connections to the connected edge devices 1062. For example, a wireless local area network (WLAN) unit may be used to implement Wi-Fi® communications in accordance with the Institute of Electrical and Electronics Engineers (IEEE) 802.11 standard. In addition, wireless wide area communications, e.g., according to a cellular or other wireless wide area protocol, may occur via a wireless wide area network (WWAN) unit.

The wireless network transceiver 1066 (or multiple transceivers) may communicate using multiple standards or radios for communications at a different range. For example, the edge computing node 1050 may communicate with close devices, e.g., within about 10 meters, using a local transceiver based on Bluetooth Low Energy (BLE), or another low power radio, to save power. More distant connected edge devices 1062, e.g., within about 50 meters, may be reached over ZigBee® or other intermediate power radios. Both communications techniques may take place over a single radio at different power levels or may take place over separate transceivers, for example, a local transceiver using BLE and a separate mesh transceiver using ZigBee®.

A wireless network transceiver 1066 (e.g., a radio transceiver) may be included to communicate with devices or services in a cloud (e.g., an edge cloud 1095) via local or wide area network protocols. The wireless network transceiver 1066 may be a low-power wide-area (LPWA) transceiver that follows the IEEE 802.15.4, or IEEE 802.15.4g standards, among others. The edge computing node 1050 may communicate over a wide area using LoRaWAN™ (Long Range Wide Area Network) developed by Semtech and the LoRa Alliance. The techniques described herein are not limited to these technologies but may be used with any number of other cloud transceivers that implement long range, low bandwidth communications, such as Sigfox, and other technologies. Further, other communications techniques, such as time-slotted channel hopping, described in the IEEE 802.15.4e specification may be used.

Any number of other radio communications and protocols may be used in addition to the systems mentioned for the wireless network transceiver 1066, as described herein. For example, the transceiver 1066 may include a cellular transceiver that uses spread spectrum (SPA/SAS) communications for implementing high-speed communications. Further, any number of other protocols may be used, such as Wi-Fi® networks for medium speed communications and provision of network communications. The transceiver 1066 may include radios that are compatible with any number of 3GPP (Third Generation Partnership Project) specifications, such as Long Term Evolution (LTE) and 5th Generation (5G) communication systems, discussed in further detail at the end of the present disclosure. A network interface controller (NIC) 1068 may be included to provide a wired communication to nodes of the edge cloud 1095 or to other devices, such as the connected edge devices 1062 (e.g., operating in a mesh). The wired communication may provide an Ethernet connection or may be based on other types of networks, such as Controller Area Network (CAN), Local Interconnect Network (LIN), DeviceNet, ControlNet, Data Highway+, PROFIBUS, or PROFINET, among many others. An additional NIC 1068 may be included to enable connecting to a second network, for example, a first NIC 1068 providing communications to the cloud over Ethernet, and a second NIC 1068 providing communications to other devices over another type of network.

Given the variety of types of applicable communications from the device to another component or network, applicable communications circuitry used by the device may include or be embodied by any one or more of components 1064, 1066, 1068, or 1070. Accordingly, in various examples, applicable means for communicating (e.g., receiving, transmitting, etc.) may be embodied by such communications circuitry.

The edge computing node 1050 may include or be coupled to acceleration circuitry 1064, which may be embodied by one or more artificial intelligence (AI) accelerators, a neural compute stick, neuromorphic hardware, an FPGA, an arrangement of GPUs, an arrangement of xPUs/DPUs/IPU/NPUs, one or more SoCs, one or more CPUs, one or more digital signal processors, dedicated ASICs, or other forms of specialized processors or circuitry designed to accomplish one or more specialized tasks. These tasks may include AI processing (including machine learning, training, inferencing, and classification operations), visual data processing, network data processing, object detection, rule analysis, or the like. These tasks also may include the specific edge computing tasks for service management and service operations discussed elsewhere in this document.

The interconnect 1056 may couple the processor 1052 to a sensor hub or external interface 1070 that is used to connect additional devices or subsystems. The devices may include sensors 1072, such as accelerometers, level sensors, flow sensors, optical light sensors, camera sensors, temperature sensors, global navigation system (e.g., GPS) sensors, pressure sensors, barometric pressure sensors, and the like. The hub or interface 1070 further may be used to connect the edge computing node 1050 to actuators 1074, such as power switches, valve actuators, an audible sound generator, a visual warning device, and the like.

In some optional examples, various input/output (I/O) devices may be present within or connected to, the edge computing node 1050. For example, a display or other output device 1084 may be included to show information, such as sensor readings or actuator position. An input device 1086, such as a touch screen or keypad may be included to accept input. An output device 1084 may include any number of forms of audio or visual display, including simple visual outputs such as binary status indicators (e.g., light-emitting diodes (LEDs)) and multi-character visual outputs, or more complex outputs such as display screens (e.g., liquid crystal display (LCD) screens), with the output of characters, graphics, multimedia objects, and the like being generated or produced from the operation of the edge computing node 1050. A display or console hardware, in the context of the present system, may be used to provide output and receive input of an edge computing system; to manage components or services of an edge computing system; identify a state of an edge computing component or service; or to conduct any other number of management or administration functions or service use cases.

A battery 1076 may power the edge computing node 1050, although, in examples in which the edge computing node 1050 is mounted in a fixed location, it may have a power supply coupled to an electrical grid, or the battery may be used as a backup or for temporary capabilities. The battery 1076 may be a lithium ion battery, or a metal-air battery, such as a zinc-air battery, an aluminum-air battery, a lithium-air battery, and the like.

A battery monitor/charger 1078 may be included in the edge computing node 1050 to track the state of charge (SoCh) of the battery 1076, if included. The battery monitor/charger 1078 may be used to monitor other parameters of the battery 1076 to provide failure predictions, such as the state of health (SoH) and the state of function (SoF) of the battery 1076. The battery monitor/charger 1078 may include a battery monitoring integrated circuit, such as an LTC4020 or an LTC2990 from Linear Technologies, an ADT7488A from ON Semiconductor of Phoenix Ariz., or an IC from the UCD90xxx family from Texas Instruments of Dallas, Tex. The battery monitor/charger 1078 may communicate the information on the battery 1076 to the processor 1052 over the interconnect 1056. The battery monitor/charger 1078 may also include an analog-to-digital (ADC) converter that enables the processor 1052 to directly monitor the voltage of the battery 1076 or the current flow from the battery 1076. The battery parameters may be used to determine actions that the edge computing node 1050 may perform, such as transmission frequency, mesh network operation, sensing frequency, and the like.

A power block 1080, or other power supply coupled to a grid, may be coupled with the battery monitor/charger 1078 to charge the battery 1076. In some examples, the power block 1080 may be replaced with a wireless power receiver to obtain the power wirelessly, for example, through a loop antenna in the edge computing node 1050. A wireless battery charging circuit, such as an LTC4020 chip from Linear Technologies of Milpitas, Calif., among others, may be included in the battery monitor/charger 1078. The specific charging circuits may be selected based on the size of the battery 1076, and thus, the current required. The charging may be performed using the Airfuel standard promulgated by the Airfuel Alliance, the Qi wireless charging standard promulgated by the Wireless Power Consortium, or the Rezence charging standard, promulgated by the Alliance for Wireless Power, among others.

The storage 1058 may include instructions 1082 in the form of software, firmware, or hardware commands to implement the techniques described herein. Although such instructions 1082 are shown as code blocks included in the memory 1054 and the storage 1058, it may be understood that any of the code blocks may be replaced with hardwired circuits, for example, built into an application specific integrated circuit (ASIC).

In an example, the instructions 1082 provided via the memory 1054, the storage 1058, or the processor 1052 may be embodied as a non-transitory, machine-readable medium 1060 including code to direct the processor 1052 to perform electronic operations in the edge computing node 1050. The processor 1052 may access the non-transitory, machine-readable medium 1060 over the interconnect 1056. For instance, the non-transitory, machine-readable medium 1060 may be embodied by devices described for the storage 1058 or may include specific storage units such as optical disks, flash drives, or any number of other hardware devices. The non-transitory, machine-readable medium 1060 may include instructions to direct the processor 1052 to perform a specific sequence or flow of actions, for example, as described with respect to the flowchart(s) and block diagram(s) of operations and functionality depicted above. As used herein, the terms “machine-readable medium” and “computer-readable medium” are interchangeable.

Also in a specific example, the instructions 1082 on the processor 1052 (separately, or in combination with the instructions 1082 of the machine readable medium 1060) may configure execution or operation of a trusted execution environment (TEE) 1090. In an example, the TEE 1090 operates as a protected area accessible to the processor 1052 for secure execution of instructions and secure access to data. Various implementations of the TEE 1090, and an accompanying secure area in the processor 1052 or the memory 1054 may be provided, for instance, through use of Intel® Software Guard Extensions (SGX) or ARM® TrustZone® hardware security extensions, Intel® Management Engine (ME), or Intel® Converged Security Manageability Engine (CSME). Other aspects of security hardening, hardware roots-of-trust, and trusted or protected operations may be implemented in the edge computing device 1050 through the TEE 1090 and the processor 1052.

FIG. 11 is a block diagram of an example processor platform 1100 structured to execute and/or instantiate the machine readable instructions and/or operations of FIGS. 6-7 to implement the model update controller circuitry 410 of FIG. 4. The processor platform 1100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 1100 of the illustrated example includes processor circuitry 1112. The processor circuitry 1112 of the illustrated example is hardware. For example, the processor circuitry 1112 can be implemented by one or more integrated circuits, logic circuits, FPGAs microprocessors, CPUs, GPUs, DSPs, and/or microcontrollers from any desired family or manufacturer. The processor circuitry 1112 may be implemented by one or more semiconductor based (e.g., silicon based) devices. In this example, the processor circuitry 1112 implements the example data interface circuitry 502, the example environmental data interface circuitry 504, the example intelligent trigger circuitry 506, the example automated model search circuitry 508, and the example intelligent deployment circuitry 510.

The processor circuitry 1112 of the illustrated example includes a local memory 1113 (e.g., a cache, registers, etc.). The processor circuitry 1112 of the illustrated example is in communication with a main memory including a volatile memory 1114 and a non-volatile memory 1116 by a bus 1118. The volatile memory 1114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1116 may be implemented by flash memory and/or any other desired type of memory device. Access to the main memory 1114, 1116 of the illustrated example is controlled by a memory controller 1117.

The processor platform 1100 of the illustrated example also includes interface circuitry 1120. The interface circuitry 1120 may be implemented by hardware in accordance with any type of interface standard, such as an Ethernet interface, a universal serial bus (USB) interface, a Bluetooth® interface, a near field communication (NFC) interface, a PCI interface, and/or a PCIe interface.

In the illustrated example, one or more input devices 1122 are connected to the interface circuitry 1120. The input device(s) 1122 permit(s) a user to enter data and/or commands into the processor circuitry 1112. The input device(s) 1122 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1124 are also connected to the interface circuitry 1120 of the illustrated example. The output devices 1124 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1120 of the illustrated example, thus, typically includes a graphics driver card, a graphics driver chip, and/or graphics processor circuitry such as a GPU.

The interface circuitry 1120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 1100 of the illustrated example also includes one or more mass storage devices 1128 to store software and/or data. Examples of such mass storage devices 1128 include magnetic storage devices, optical storage devices, floppy disk drives, HDDs, CDs, Blu-ray disk drives, redundant array of independent disks (RAID) systems, solid state storage devices such as flash memory devices, and DVD drives.

The machine executable instructions 1132, which may be implemented by the machine readable instructions of FIGS. 6-7, may be stored in the mass storage device 1128, in the volatile memory 1114, in the non-volatile memory 1116, and/or on a removable non-transitory computer readable storage medium such as a CD or DVD.

FIG. 12 is a block diagram of an example implementation of the processor circuitry 1112 of FIG. 11. In this example, the processor circuitry 1112 of FIG. 11 is implemented by a microprocessor 1200. For example, the microprocessor 1200 may implement multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores. The cores 1202 of the microprocessor 1200 may operate independently or may cooperate to execute machine readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine readable instructions and/or operations represented by the flowcharts of FIGS. 6-7.

The cores 1202 may communicate by an example first bus 1204. In some examples, the first bus 1204 may implement a communication bus to effectuate communication associated with one(s) of the cores 1202. For example, the first bus 1204 may implement at least one of an Inter-Integrated Circuit (I2C) bus, a Serial Peripheral Interface (SPI) bus, a PCI bus, or a PCIe bus. Additionally or alternatively, the first bus 1204 may implement any other type of computing or electrical bus. The cores 1202 may obtain data, instructions, and/or signals from one or more external devices by example interface circuitry 1206. The cores 1202 may output data, instructions, and/or signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2_cache)) for high-speed access to data and/or instructions. Data and/or instructions may be transferred (e.g., shared) by writing to and/or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry (sometimes referred to as an ALU) 1216, a plurality of registers 1218, the L1 cache 1220, and an example second bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic and/or logic operations on the data within the corresponding core 1202. The AL circuitry 1216 of some examples performs integer based operations. In other examples, the AL circuitry 1216 also performs floating point operations. In yet other examples, the AL circuitry 1216 may include first AL circuitry that performs integer based operations and second AL circuitry that performs floating point operations. In some examples, the AL circuitry 1216 may be referred to as an Arithmetic Logic Unit (ALU). The registers 1218 are semiconductor-based structures to store data and/or instructions such as results of one or more of the operations performed by the AL circuitry 1216 of the corresponding core 1202. For example, the registers 1218 may include vector register(s), SIMD register(s), general purpose register(s), flag register(s), segment register(s), machine specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure including distributed throughout the core 1202 to shorten access time. The second bus 1222 may implement at least one of an I2C bus, a SPI bus, a PCI bus, or a PCIe bus.

Each core 1202 and/or, more generally, the microprocessor 1200 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1200 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 13 is a block diagram of another example implementation of the processor circuitry 1112 of FIG. 11. In this example, the processor circuitry 1112 is implemented by FPGA circuitry 1300. The FPGA circuitry 1300 can be used, for example, to perform operations that could otherwise be performed by the example microprocessor 1200 of FIG. 12 executing corresponding machine readable instructions. However, once configured, the FPGA circuitry 1300 instantiates the machine readable instructions in hardware and, thus, can often execute the operations faster than they could be performed by a general purpose microprocessor executing the corresponding software.

More specifically, in contrast to the microprocessor 1200 of FIG. 12 described above (which is a general purpose device that may be programmed to execute some or all of the machine readable instructions represented by the flowchart of FIGS. 6-7 but whose interconnections and logic circuitry are fixed once fabricated), the FPGA circuitry 1300 of the example of FIG. 13 includes interconnections and logic circuitry that may be configured and/or interconnected in different ways after fabrication to instantiate, for example, some or all of the machine readable instructions represented by the flowchart of FIGS. 6-7. In particular, the FPGA 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the software represented by the flowchart of FIGS. 6-7. As such, the FPGA circuitry 1300 may be structured to effectively instantiate some or all of the machine readable instructions of the flowchart of FIGS. 6-7 as dedicated logic circuits to perform the operations corresponding to those software instructions in a dedicated manner analogous to an ASIC. Therefore, the FPGA circuitry 1300 may perform the operations corresponding to the some or all of the machine readable instructions of FIGS. 6-7 faster than the general purpose microprocessor can execute the same.

In the example of FIG. 13, the FPGA circuitry 1300 is structured to be programmed (and/or reprogrammed one or more times) by an end user by a hardware description language (HDL) such as Verilog. The FPGA circuitry 1300 of FIG. 13, includes example input/output (I/O) circuitry 1302 to obtain and/or output data to/from example configuration circuitry 1304 and/or external hardware (e.g., external hardware circuitry) 1306. For example, the configuration circuitry 1304 may implement interface circuitry that may obtain machine readable instructions to configure the FPGA circuitry 1300, or portion(s) thereof. In some such examples, the configuration circuitry 1304 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 1306 may implement the microprocessor 1300 of FIG. 13. The FPGA circuitry 1300 also includes an array of example logic gate circuitry 1308, a plurality of example configurable interconnections 1310, and example storage circuitry 1312. The logic gate circuitry 1308 and interconnections 1310 are configurable to instantiate one or more operations that may correspond to at least some of the machine readable instructions of FIGS. 6-7 and/or other desired operations. The logic gate circuitry 1308 shown in FIG. 13 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of the electrical structures and/or the logic gates to form circuits to perform desired operations. The logic gate circuitry 1308 may include other electrical structures such as look-up tables (LUTs), registers (e.g., flip-flops or latches), multiplexers, etc.

The interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example Dedicated Operations Circuitry 1314. In this example, the Dedicated Operations Circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 and/or an example DSP 1322. Other general purpose programmable circuitry 1318 may additionally or alternatively be present such as a GPU, an XPU, etc., that can be programmed to perform other operations.

Although FIGS. 12 and 13 illustrate two example implementations of the processor circuitry 1112 of FIG. 11, many other approaches are contemplated. For example, as mentioned above, modern FPGA circuitry may include an on-board CPU, such as one or more of the example CPU 1320 of FIG. 13. Therefore, the processor circuitry 1112 of FIG. 11 may additionally be implemented by combining the example microprocessor 1200 of FIG. 12 and the example FPGA circuitry 1300 of FIG. 13. In some such hybrid examples, a first portion of the machine readable instructions represented by the flowchart of FIGS. 6-7 may be executed by one or more of the cores 1202 of FIG. 12 and a second portion of the machine readable instructions represented by the flowchart of FIGS. 6-7 may be executed by the FPGA circuitry 1300 of FIG. 13.

In some examples, the processor circuitry 1112 of FIG. 11 may be in one or more packages. For example, the processor circuitry 1112 of FIG. 11 and/or the FPGA circuitry 1300 of FIG. 13 may be in one or more packages. In some examples, an XPU may be implemented by the processor circuitry 1112 of FIG. 11, which may be in one or more packages. For example, the XPU may include a CPU in one package, a DSP in another package, a GPU in yet another package, and an FPGA in still yet another package.

A block diagram illustrating an example software distribution platform 1405 to distribute software such as the example machine readable instructions 1132 of FIG. 11 to hardware devices owned and/or operated by third parties is illustrated in FIG. 11. The example software distribution platform 1405 may be implemented by any computer server, data facility, cloud service, etc., capable of storing and transmitting software to other computing devices. The third parties may be customers of the entity owning and/or operating the software distribution platform 1405. For example, the entity that owns and/or operates the software distribution platform 1405 may be a developer, a seller, and/or a licensor of software such as the example machine readable instructions 1132 of FIG. 11. The third parties may be consumers, users, retailers, OEMs, etc., who purchase and/or license the software for use and/or re-sale and/or sub-licensing. In the illustrated example, the software distribution platform 1405 includes one or more servers and one or more storage devices. The storage devices store the machine readable instructions 1132, which may correspond to the example machine readable instructions 600 and 700 of FIGS. 6-7, as described above. The one or more servers of the example software distribution platform 1405 are in communication with a network 1410, which may correspond to any one or more of the Internet and/or any of the example networks 1410 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1132 from the software distribution platform 1405. For example, the software, which may correspond to the example machine readable instructions 1132 of FIG. 11, may be downloaded to the example processor platform 1100, which is to execute the machine readable instructions 1132 to implement the model update controller circuitry 410. In some examples, one or more servers of the software distribution platform 1405 periodically offer, transmit, and/or force updates to the software (e.g., the example machine readable instructions 1132 of FIG. 11) to ensure improvements, patches, updates, etc., are distributed and applied to the software at the end user devices.

From the foregoing, it will be appreciated that example methods, apparatus and articles of manufacture have been disclosed that automatically update artificial intelligence models for autonomous factories without using human supervision. The disclosed methods, apparatus and articles of manufacture improve the efficiency of using a computing device by reducing wasted resources and inefficiencies as sub-optimal models are running which predict faulty rates for manufacturing processes in factories. The disclosed methods, apparatus and articles of manufacture are accordingly directed to one or more improvement(s) in the functioning of a computer.

Example methods, apparatus, systems, and articles of manufacture to automatically update artificial intelligence models for autonomous factories are disclosed herein. Further examples and combinations thereof include the following:

Example 1 includes an apparatus for automatically updating artificial intelligence models operating on data of a first factory production line, the apparatus comprising an intelligent trigger circuitry to trigger an automated model update process, an automated model search circuitry to, in response to a model update, generate a plurality of candidate artificial intelligence models, and an intelligent model deployment circuitry to output a prediction of an artificial intelligence model combination to improve prediction performance over time.

Example 2 includes the apparatus of example 1, wherein the intelligent trigger circuitry is to trigger the model update based on at least one of a metric baseline, an output from a first artificial intelligence model operating on the data of the first factory production line, metadata, and an output from a second artificial intelligence model, wherein the second artificial intelligence model is operating on data of a second factory production line.

Example 3 includes the apparatus of example 2, wherein the metadata includes at least one of environmental sensor readings, equipment configurations, and process configurations.

Example 4 includes the apparatus of example 1, further including a first artificial intelligence model operating on the data of the first factory production line, wherein the automated search circuitry, in response to the intelligent trigger circuitry triggering the automated model update process, generates a plurality of candidate artificial intelligence models or selects a plurality of candidate artificial intelligence models from a repository of trained artificial intelligence models.

Example 5 includes the apparatus of example 4, wherein a first candidate artificial intelligence model of the plurality of candidate artificial intelligence models implements a model architecture of the first artificial intelligence model operating on the data of the first factory production line, further including updated model parameters based on newly collected data.

Example 6 includes the apparatus of example 4, wherein a second candidate artificial intelligence model of the plurality of candidate artificial intelligence models implements a similar model architecture of the first artificial intelligence model operating on the data of the first factory production line, further including hyperparameter updates.

Example 7 includes the apparatus of example 4, wherein a third candidate artificial intelligence model of the plurality of candidate artificial intelligence models implements a model architecture not based on a model architecture of the first artificial intelligence model operating on the data of the first factory production line.

Example 8 includes the apparatus of example 4, wherein the automated model search circuitry selects a first candidate artificial intelligence model from a repository of trained artificial intelligence models based on a similarity score and a performance score.

Example 9 includes the apparatus of example 4, wherein the intelligent model deployment circuitry runs the plurality of candidate artificial intelligence models in parallel and the intelligent model deployment circuitry removes outlier candidate artificial intelligence models from the plurality of candidate artificial intelligence models based on an output of the plurality of candidate artificial intelligence models.

Example 10 includes an apparatus comprising a non-transitory computer readable medium, instructions at the apparatus, a logic circuit to execute the instructions to at least trigger an automated model update process, in response to a model update, generate a plurality of candidate artificial intelligence models, and output a prediction of an artificial intelligence model combination to improve prediction performance over time.

Example 11 includes the non-transitory computer readable medium of example 10, wherein the instructions, when executed, further cause the logic circuit to trigger the model update based on at least one of a metric baseline, an output from a first artificial intelligence model operating on data of a first factory production line, metadata, and an output from a second artificial intelligence model, wherein the second artificial intelligence model is operating on data of a second factory production line.

Example 12 includes the non-transitory computer readable medium of example 11, wherein the metadata includes at least one of environmental sensor readings, equipment configurations, and process configurations.

Example 13 includes the non-transitory computer readable medium of example 10, further including a first artificial intelligence model operating on data of a first factory production line, wherein the instructions, when executed, further cause the logic circuit to, in response to a triggered automated model update process, generate a plurality of candidate artificial intelligence models or selects a plurality of artificial intelligence models from a repository of trained artificial intelligence models.

Example 14 includes the non-transitory computer readable medium of example 13, wherein a first candidate artificial intelligence model of the plurality of candidate artificial intelligence models implements a model architecture of the first artificial intelligence model operating on the data of a first factory production line, further including updated model parameters based on newly collected data.

Example 15 includes the non-transitory computer readable medium of example 13, wherein a second candidate artificial intelligence model of the plurality of candidate artificial intelligence models implements a similar model architecture of the first artificial intelligence model operating on the data of a first factory production line, further including hyperparameter updates.

Example 16 includes the non-transitory computer readable medium of example 13, wherein a third candidate artificial intelligence model of the plurality of candidate artificial intelligence models implements a model architecture not based on a model architecture of a first artificial intelligence model operating on the data of the first factory production line.

Example 17 includes the non-transitory computer readable medium of example 13, wherein the instructions, when executed, further cause the logic circuit to select a first candidate artificial intelligence model from a repository of trained artificial intelligence models based on a similarity score and a performance score.

Example 18 includes the non-transitory computer readable medium of example 13, wherein the instructions, when executed, further cause the logic circuit to run the plurality of candidate artificial intelligence models in parallel and, remove outlier candidate artificial intelligence models from the plurality of candidate artificial intelligence models based on an output of the plurality of candidate artificial intelligence models.

Example 19 includes an apparatus comprising at least one memory, instructions in the apparatus, and processor circuitry including control circuitry to control data movement within the processor circuitry, arithmetic and logic circuitry to perform one or more operations on the data, and one or more registers to store a result of one or more operations, the processor circuitry to execute the instructions to trigger an automated model update process, in response to a model update, generate a plurality of candidate artificial intelligence models, and output a prediction of an artificial intelligence model combination to improve prediction performance over time.

Example 20 includes the apparatus of example 19, wherein the processor circuitry further executes the instructions to trigger the model update based on at least one of a metric baseline, an output from a first artificial intelligence model operating on data of a first factory production line, metadata, and an output from a second artificial intelligence model, wherein the second artificial intelligence model is operating on data of a second factory production line.

Example 21 includes the apparatus of example 20, wherein the metadata includes at least one of environmental sensor readings, equipment configurations, and process configurations.

Example 22 includes the apparatus of example 19, further including a first artificial intelligence model operating on data of a first factory production line, wherein the processor circuitry, in response to a triggered automated model update process, further executes instructions to generate a plurality of candidate artificial intelligence models or select a plurality of artificial intelligence models from a repository of trained artificial intelligence models.

Example 23 includes the apparatus of example 22, wherein a first candidate artificial intelligence model of the plurality of candidate artificial intelligence models implements a model architecture of the first artificial intelligence model operating on the data of the first factory production line, further including updated model parameters based on newly collected data.

Example 24 includes the apparatus of example 22, wherein a second candidate artificial intelligence model of the plurality of candidate artificial intelligence models implements a similar model architecture of the first artificial intelligence model operating on the data of the first factory production line, further including hyperparameter updates.

Example 25 includes the apparatus of example 22, wherein a third candidate artificial intelligence model of the plurality of candidate artificial intelligence models implements a model architecture not based on a model architecture of the first artificial intelligence model operating on the data of the first factory production line.

Example 26 includes the apparatus of example 22, wherein the processor circuitry further executes the instructions to select a first candidate artificial intelligence model from a repository of trained artificial intelligence models based on a similarity score and a performance score.

Example 27 includes the apparatus of example 22, wherein the processor circuitry further executes the instructions to run the plurality of candidate artificial intelligence models in parallel and remove outlier candidate artificial intelligence models from the plurality of candidate artificial intelligence models based on an output of the plurality of candidate artificial intelligence models.

Example 28 includes a method for automatically updating artificial intelligence models operating on data of a first factory production line, the method comprising triggering an automated model update process, in response to a model update, generating a plurality of candidate artificial intelligence models, and outputting a prediction of an artificial intelligence model combination to improve prediction performance over time.

Example 29 includes the method of example 28, wherein the method further includes triggering the model update based on at least one of a metric baseline, an output from a first artificial intelligence model operating on the data of the first factory production line, metadata, and an output from a second artificial intelligence model, wherein the second artificial intelligence model is operating on data of a second factory production line.

Example 30 includes the method of example 29, wherein the metadata includes at least one of environmental sensor readings, equipment configurations, and process configurations.

Example 31 includes the method of example 28, further including a first artificial intelligence model operating on the data of the first factory production line, in response to a triggered automated model update process, generating a plurality of candidate artificial intelligence models or selecting a plurality of artificial intelligence models from a repository of trained artificial intelligence models.

Example 32 includes the method of example 31, wherein a first candidate artificial intelligence model of the plurality of candidate artificial intelligence models implements a model architecture of the first artificial intelligence model operating on the data of the first factory production line, further including updated model parameters based on newly collected data.

Example 33 includes the method of example 31, wherein a second candidate artificial intelligence model of the plurality of candidate artificial intelligence models implements a similar model architecture of the first artificial intelligence model operating on the data of the first factory production line, further including hyperparameter updates.

Example 34 includes the method of example 31, wherein a third candidate artificial intelligence model of the plurality of candidate artificial intelligence models implements a model architecture not based on a model architecture of the first artificial intelligence model operating on the data of the first factory production line.

Example 35 includes the method of example 31, further including selecting a first candidate artificial intelligence model from a repository of trained artificial intelligence models based on a similarity score and a performance score.

Example 36 includes the method of example 31, further including running the plurality of candidate artificial intelligence models in parallel and removing outlier candidate artificial intelligence models from the plurality of candidate artificial intelligence models based on an output of the plurality of candidate artificial intelligence models.

Example 37 includes an apparatus for automatically updating artificial intelligence models operating on data of a first factory production line, the apparatus comprising means for triggering an automated model update process, means for, in response to a model update, generating a plurality of candidate artificial intelligence models, and means for outputting a prediction of an artificial intelligence model combination to improve prediction performance over time.

Example 38 includes the apparatus of example 37, the apparatus further including means for triggering the model update based on at least one of a metric baseline, an output from a first artificial intelligence model operating on the data of the first factory production line, metadata, and an output from a second artificial intelligence model, wherein the second artificial intelligence model is operating on data of a second factory production line.

Example 39 includes the apparatus of example 38, wherein the metadata includes at least one of environmental sensor readings, equipment configurations, and process configurations.

Example 40 includes the apparatus of example 37, further including a first artificial intelligence model operating on the first factory production line, wherein in response to the means for triggering the automated model update process triggering the automated model update process, further including means for generating a plurality of candidate artificial intelligence models or means for selecting a plurality of artificial intelligence models from a repository of trained artificial intelligence models.

Example 41 includes the apparatus of example 40, wherein a first candidate artificial intelligence model of the plurality of candidate artificial intelligence models implements a model architecture of the first artificial intelligence model operating on the data of the first factory production line, further including updated model parameters based on newly collected data.

Example 42 includes the apparatus of example 40, wherein a second candidate artificial intelligence model of the plurality of candidate artificial intelligence models implements a similar model architecture of the first artificial intelligence model operating on the data of the first factory production line, further including hyperparameter updates.

Example 43 includes the apparatus of example 40, wherein a third candidate artificial intelligence model of the plurality of candidate artificial intelligence models implements a model architecture not based on a model architecture of the first artificial intelligence model operating on the data of the first factory production line.

Example 44 includes the apparatus of example 40, further including means for selecting a first candidate artificial intelligence model from a repository of trained artificial models based on a similarity score and a performance score.

Example 45 includes the apparatus of example 40, further including means for running the plurality of candidate artificial intelligence models in parallel and means for removing outlier candidate artificial intelligence models from the plurality of candidate artificial intelligence models based on an output of the plurality of candidate artificial intelligence models.

Example 46 includes a system comprising a first internet of things (IoT) sensor corresponding to factory conditions of a first factory production line, a second IoT sensor corresponding to factory conditions of a second factory production line, a model update device including intelligent trigger circuitry to receive metadata from the first IoT sensor and the second IoT sensor, the intelligent trigger circuitry to update at least one artificial intelligence model operating on data of the first factory production line, automated model search circuitry to, in response to the model update, generate a plurality of candidate artificial intelligence models, and intelligent model deployment circuitry to output a prediction of an artificial intelligence model combination to improve prediction performance over time.

Example 47 includes the system of example 46, wherein the model update device receives metadata from the first IoT sensor and the second IoT sensor, and in response to a threshold of similarity between the metadata from the first IoT sensor and the metadata of the second IoT sensor, triggering the model update.

Example 48 includes the system of example 46, wherein the intelligent trigger circuitry is to trigger the model update based on at least one of a metric baseline, an output from a first artificial intelligence model operating on the data of the first factory production line, metadata, and an output from a second artificial intelligence model, wherein the second artificial intelligence model is operating on data of a second factory production line.

Example 49 includes the system of example 48, wherein the metadata includes at least one of environmental sensor readings, equipment configurations, and process configurations.

Example 50 includes the system of example 46, further including a first artificial intelligence model operating on the data of the first factory production line, wherein the automated search circuitry, in response to the intelligent trigger circuitry triggering the automated model update process, generates a plurality of candidate artificial intelligence models or selects a plurality of candidate artificial intelligence models from a repository of trained artificial intelligence models.

Example 51 includes the system of example 50, wherein a first candidate artificial intelligence model of the plurality of candidate artificial intelligence models implements a model architecture of the first artificial intelligence model operating on the data of the first factory production line, further including updated model parameters based on newly collected data.

Example 52 includes the system of example 50, wherein a second candidate artificial intelligence model of the plurality of candidate artificial intelligence models implements a similar model architecture of the first artificial intelligence model operating on the data of the first factory production line, further including hyperparameter updates.

Example 53 includes the system of example 50, wherein a third candidate artificial intelligence model of the plurality of candidate artificial intelligence models implements a model architecture not based on a model architecture of the first artificial intelligence model operating on the data of the first factory production line.

Example 54 includes the system of example 50, wherein the automated model search circuitry selects a first candidate artificial intelligence model from a repository of trained artificial intelligence models based on a similarity score and a performance score.

Example 55 includes the system of example 50, wherein the intelligent model deployment circuitry runs the plurality of candidate artificial intelligence models in parallel and the intelligent model deployment circuitry removes outlier candidate artificial intelligence models from the plurality of candidate artificial intelligence models based on an output of the plurality of candidate artificial intelligence models.

Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

The following claims are hereby incorporated into this Detailed Description by this reference, with each claim standing on its own as a separate embodiment of the present disclosure.

1. An apparatus for automatically updating artificial intelligence models operating on data of a first factory production line, the apparatus comprising:
an intelligent trigger circuitry to trigger an automated model update process;
an automated model search circuitry to, in response to a model update, generate a plurality of candidate artificial intelligence models; and
an intelligent model deployment circuitry to output a prediction of an artificial intelligence model combination to improve prediction performance over time.

2. The apparatus of claim 1, wherein the intelligent trigger circuitry is to trigger the model update based on at least one of: a metric baseline, an output from a first artificial intelligence model operating on the data of the first factory production line, metadata, and an output from a second artificial intelligence model, wherein the second artificial intelligence model is operating on data of a second factory production line.

3. The apparatus of claim 2, wherein the metadata includes at least one of environmental sensor readings, equipment configurations, and process configurations.

4. The apparatus of claim 1, further including a first artificial intelligence model operating on the data of the first factory production line, wherein the automated search circuitry, in response to the intelligent trigger circuitry triggering the automated model update process, generates a plurality of candidate artificial intelligence models or selects a plurality of candidate artificial intelligence models from a repository of trained artificial intelligence models.

5. The apparatus of claim 4, wherein a first candidate artificial intelligence model of the plurality of candidate artificial intelligence models implements a model architecture of the first artificial intelligence model operating on the data of the first factory production line, further including updated model parameters based on newly collected data.

6. The apparatus of claim 4, wherein a second candidate artificial intelligence model of the plurality of candidate artificial intelligence models implements a similar model architecture of the first artificial intelligence model operating on the data of the first factory production line, further including hyperparameter updates.

7. The apparatus of claim 4, wherein a third candidate artificial intelligence model of the plurality of candidate artificial intelligence models implements a model architecture not based on a model architecture of the first artificial intelligence model operating on the data of the first factory production line.

8. The apparatus of claim 4, wherein the automated model search circuitry selects a first candidate artificial intelligence model from a repository of trained artificial intelligence models based on a similarity score and a performance score.

9. The apparatus of claim 4, wherein the intelligent model deployment circuitry runs the plurality of candidate artificial intelligence models in parallel and the intelligent model deployment circuitry removes outlier candidate artificial intelligence models from the plurality of candidate artificial intelligence models based on an output of the plurality of candidate artificial intelligence models.

10. An apparatus comprising:
a non-transitory computer readable medium;
instructions at the apparatus;
a logic circuit to execute the instructions to at least:
trigger an automated model update process;
in response to a model update, generate a plurality of candidate artificial intelligence models; and
output a prediction of an artificial intelligence model combination to improve prediction performance over time.

11. The non-transitory computer readable medium of claim 10, wherein the instructions, when executed, further cause the logic circuit to trigger the model update based on at least one of: a metric baseline, an output from a first artificial intelligence model operating on data of a first factory production line, metadata, and an output from a second artificial intelligence model, wherein the second artificial intelligence model is operating on data of a second factory production line.

12. The non-transitory computer readable medium of claim 11, wherein the metadata includes at least one of environmental sensor readings, equipment configurations, and process configurations.

13. The non-transitory computer readable medium of claim 10, further including a first artificial intelligence model operating on data of a first factory production line, wherein the instructions, when executed, further cause the logic circuit to, in response to a triggered automated model update process, generate a plurality of candidate artificial intelligence models or selects a plurality of artificial intelligence models from a repository of trained artificial intelligence models.

14. The non-transitory computer readable medium of claim 13, wherein a first candidate artificial intelligence model of the plurality of candidate artificial intelligence models implements a model architecture of the first artificial intelligence model operating on the data of a first factory production line, further including updated model parameters based on newly collected data.

15. The non-transitory computer readable medium of claim 13, wherein a second candidate artificial intelligence model of the plurality of candidate artificial intelligence models implements a similar model architecture of the first artificial intelligence model operating on the data of a first factory production line, further including hyperparameter updates.

16. The non-transitory computer readable medium of claim 13, wherein a third candidate artificial intelligence model of the plurality of candidate artificial intelligence models implements a model architecture not based on a model architecture of a first artificial intelligence model operating on the data of the first factory production line.

17. The non-transitory computer readable medium of claim 13, wherein the instructions, when executed, further cause the logic circuit to select a first candidate artificial intelligence model from a repository of trained artificial intelligence models based on a similarity score and a performance score.

18. The non-transitory computer readable medium of claim 13, wherein the instructions, when executed, further cause the logic circuit to run the plurality of candidate artificial intelligence models in parallel and, remove outlier candidate artificial intelligence models from the plurality of candidate artificial intelligence models based on an output of the plurality of candidate artificial intelligence models.

19. An apparatus comprising:
at least one memory;
instructions in the apparatus; and
processor circuitry including control circuitry to control data movement within the processor circuitry, arithmetic and logic circuitry to perform one or more operations on the data, and one or more registers to store a result of one or more operations, the processor circuitry to execute the instructions to:
trigger an automated model update process;
in response to a model update, generate a plurality of candidate artificial intelligence models; and
output a prediction of an artificial intelligence model combination to improve prediction performance over time.

20. The apparatus of claim 19, wherein the processor circuitry further executes the instructions to trigger the model update based on at least one of: a metric baseline, an output from a first artificial intelligence model operating on data of a first factory production line, metadata, and an output from a second artificial intelligence model, wherein the second artificial intelligence model is operating on data of a second factory production line.

21. (canceled)

22. (canceled)

23. (canceled)

24. (canceled)

25. (canceled)

26. (canceled)

27. (canceled)

28. A method for automatically updating artificial intelligence models operating on data of a first factory production line, the method comprising:
triggering an automated model update process;
in response to a model update, generating a plurality of candidate artificial intelligence models; and
outputting a prediction of an artificial intelligence model combination to improve prediction performance over time.

29. The method of claim 28, wherein the method further includes triggering the model update based on at least one of: a metric baseline, an output from a first artificial intelligence model operating on the data of the first factory production line, metadata, and an output from a second artificial intelligence model, wherein the second artificial intelligence model is operating on data of a second factory production line.

30. (canceled)

31. (canceled)

32. (canceled)

33. (canceled)

34. (canceled)

35. (canceled)

36. (canceled)

37. An apparatus for automatically updating artificial intelligence models operating on data of a first factory production line, the apparatus comprising:
means for triggering an automated model update process;
means for, in response to a model update, generating a plurality of candidate artificial intelligence models; and
means for outputting a prediction of an artificial intelligence model combination to improve prediction performance over time.

38. The apparatus of claim 37, the apparatus further including means for triggering the model update based on at least one of: a metric baseline, an output from a first artificial intelligence model operating on the data of the first factory production line, metadata, and an output from a second artificial intelligence model, wherein the second artificial intelligence model is operating on data of a second factory production line.

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)
